(19) United States
(12) Patent Application Publication
(10) Pub. No.: US 2015/0123108 A1
(43) Pub. Date: May 7, 2015

(54) ORGANIC ELECTROLUMINESCENCE ELEMENT, METHOD FOR PRODUCING ORGANIC ELECTROLUMINESCENCE ELEMENT AND ORGANIC ELECTROLUMINESCENCE MODULE

(71) Applicant: Konica Minolta, Inc., Tokyo (JP)

(72) Inventor: Takashi UDA, Tokyo (JP)

(21) Appl. No.: 14/536,155

(22) Filed: Nov. 7, 2014

(30) Foreign Application Priority Data
Nov. 7, 2013 (JP) 2013-231512

(51) Int. Cl. H01L 51/50; H01L 51/56; H01L 51/52; H01L 51/00

(52) U.S. Cl. CPC H01L 51/504; H01L 51/0014; H01L 51/56; H01L 51/5262; H01L 51/5088; H01L 51/5056; H01L 2251/558
USPC 257/40; 438/34

(57) ABSTRACT

Provided is an organic electroluminescence element that eliminates uneven light emission and changes a light emitting pattern. The organic electroluminescence element including: a supporting substrate; a first electrode; N sets of light emitting units including one or more organic functional layers, where N represents an integer of 2 or more; and one or more (N−1) sets of intermediate metal layers with optical transparency, each disposed between the adjacent light emitting units; and a second electrode. Herein, at least one organic functional layer of each light emitting unit is a layer subjected to patterning using a mask during formation of the organic functional layer, a layer subjected to patterning via light irradiation after formation of the organic functional layer, or a layer subjected to patterning using a mask during formation of the organic functional layer and further subjected to patterning via light irradiation after the formation of the organic functional layer.

### CROSS REFERENCE

The present invention claims priority under 35 U.S.C. §119 to Japanese Application No. 2013-231512, filed Nov. 7, 2013, the entire content of which is incorporated herein by reference.

### BACKGROUND OF THE INVENTION

1. Field of the Invention

The present invention relates to an organic electroluminescence element, a method for producing an organic electroluminescence element, and an organic electroluminescence module. More specifically, the present invention relates to an organic electroluminescence element that eliminates uneven light emission and is capable of changing a light emitting pattern, a method for producing the organic electroluminescence element, and a module including the organic electroluminescence element.

2. Description of the Related Art

Recently, much attention has been paid to a light emitting diode (LED) with a light guide plate, working as a planer light source (hereinafter, referred to as an LED system with light guide plate) and an organic light emitting diode (OLED: hereinafter, referred to as an organic electroluminescence element). The LED system with light guide plate has been increasingly used in various applications and situations including a backlight for a liquid crystal display (LCD) (see, for example, U.S. Pat. No. 8,330,724B) as well as a generic illumination device.

It should be noted that production of smart devices (e.g., a smart phone and a tablet) has been increased since around 2008, and the LED system with light guide plate has been used for such devices.

The LED system with light guide plate is mainly applied to a backlight for a main display (e.g., LCD). In another application, the LED system with light guide plate is often included in a device as a backlight for common function key buttons arranged at a lower part of the device.

In many cases, three types of buttons are used for common function key buttons, mainly including a home button (e.g., displayed as a rectangular mark, etc.), a return button (e.g., displayed as an arrow mark, etc.), and a search button (e.g., displayed as a magnifying glass mark, etc.).

Generally, those common function key buttons are configured by printing a pattern of a mark to be displayed on a cover glass; and disposing the above mentioned LED system with light guide plate inside the cover glass. In this configuration, light is emitted from the LED as needed, and is guided through a light guide plate (i.e. film). Then, the light passes through a dot-shaped diffusion member printed on the pattern area, and is extracted at a display side.

However, several problems exist to realize the above light emission through the common function key buttons, when using an LED system with light guide plate.

First, a light guide panel (i.e., film) should be made thinner because of a limited space for arranging an LED. However, such a thinner light guide panel leads to decrease in instrument efficiency when compared to light emission efficiency of an LED light source.

Second, the light is guided through the side of a key display, and thereby uneven emission brightness occurs corresponding to a pattern or the shape of a key button. Therefore, in order to solve this problem, the number of LED light sources should be increased, resulting in increase in the cost and power consumption.

Third, it is hard to change a key display corresponding to various situations. Hereby, to change the key display, a plurality of units of LED system with light guide plate should be stacked, leading to increase in the total thickness and cost.

Due to the above described problems, currently, display of common function key buttons is limited to only one type of a key unit which greatly causes uneven light emission such that dot-shapes are visually recognized through guiding light, regardless of any situations.

In view of user's needs, demanded is a common function key unit capable of solving the above three problems. More specifically, demanded is a common key unit, for example, in which a direction of an arrow mark displayed on a key button may be appropriately changed corresponding to the orientation of a screen. Further, a common key unit is also demanded, in which an emission color of the key button may be appropriately changed corresponding to a remaining battery capacity and/or a sender and light is uniformly emitted without causing uneven emission. Additionally, another common key unit is further demanded, in which a shape of a key button cannot be visually recognized when no light is emitted.

However, those common function key units thus demanded have not been realized to date via use of the LED system with light guide plate.

Moreover, there is an additional problem so as to realize such a common function key unit as demanded described hereinbefore. That is, it is possible to perform patterning of a shape corresponding to a key display by using a mask during film deposition of an organic electroluminescence element, and then to perform patterning via light irradiation after the film deposition (see, for example, JP-2793373B, JP2005-183045A, and JP2012-28335A).

However, in spite of the above techniques, it is not possible to realize a light emitting pattern in which a light emission shape and an emission color of an optional mark can be changed corresponding to the circumstances.

### SUMMARY OF THE INVENTION

The present invention has been made in view of the above mentioned problems and situations. Herein, an object of the present invention is to provide an organic electroluminescence element which eliminates uneven light emission and is capable of changing a light emission pattern, a method for producing the organic electroluminescence element, and an organic electroluminescence module including the organic electroluminescence element.

For achieving the object, the present inventors have investigated the cause of the problems, and obtained the following findings. That is, at least one organic functional layer of each light emitting unit may be a layer subjected to patterning using a mask during formation of the organic functional layer. At least one organic functional layer may be a layer subjected to patterning via light irradiation after formation of the organic functional layer. Alternatively, at least one function layer may be a layer subjected to patterning using a mask during formation of the organic functional layer and further subjected to patterning via light irradiation after the formation of the organic functional layer.

Accordingly, the present inventors have found that the above configuration allows an organic electroluminescence element to eliminate uneven light emission and change a light emitting pattern, which leads to the present invention.

That is, the following configuration and method allow the object of the present invention to be obtained.

1. An organic electroluminescence element including: a supporting substrate; a first electrode disposed on the supporting substrate; N sets of (N represents an integer of 2 or more) light emitting units including one or more organic functional layers; (N−1) sets of intermediate metal layers with optical transparency, each disposed between the adjacent light emitting units; and a second electrode, as being stacked to form the organic electroluminescence element.

In the N-sets of light emitting units, at least one organic functional layer of each light emitting unit includes a layer subjected to patterning using a mask during formation of the organic functional layer, a layer subjected to patterning via light irradiation after formation of the organic functional layer, or a layer subjected to patterning using a mask during formation of the organic functional layer and further subjected to patterning via light irradiation after the formation of the organic functional layer. The N sets of light emitting units are electrically operable individually or simultaneously.

2. The organic electroluminescence element according to the above aspect 1 having the following features. Shapes of the patterning in a stacking direction of each light emitting unit are not the same. Among the N sets of light emitting units, in a second to Nth light emitting units excluding a first light emitting unit placed closest to an electrode at a light emitting surface side, at least one organic functional layer of each light emitting unit is subjected to patterning using a mask during formation of the organic functional layer.

Alternatively, such at least one organic functional layer is subjected to patterning using a mask during formation of the organic functional layer and further subjected to patterning via light irradiation after the formation of the organic functional layer.

3. The organic electroluminescence element according to the aspect 1 or 2 having the following feature. The organic functional layer subjected to patterning using a mask during formation of the organic functional layer includes a hole injection layer.

4. The organic electroluminescence element according to the aspect 3 having the following feature. The organic functional layer subjected to patterning using a mask during formation of the organic functional layer is a hole injection layer.

5. The organic electroluminescence element according to the aspect 4 having the following feature. The hole injection layer has a thickness of from 2 to 50 nm.

6. The organic electroluminescence element according to the aspect 4 or 5 having the following features. Each of the N sets of light emitting units includes a hole transport layer adjacent to the hole injection layer, and the hole transport layer has a thickness of from 15 to 200 nm.

7. A method for producing an organic electroluminescence element formed by stacking a supporting substrate, a first electrode, N sets of (N represents an integer of 2 or more) light emitting units having one or more organic functional layers, one or more (N−1) sets of intermediate metal layers with optical transparency, each intermediate metal layer being disposed between the adjacent light emitting units, and a second electrode.

The method includes patterning process in which at least one organic functional layer of each light emitting unit is subjected to patterning. Herein, the patterning of the organic functional layer during the patterning process includes patterning conducted via using a mask during formation of the organic functional layer, patterning conducted via light irradiation after formation of the organic functional layer, or patterning conducted using a mask during formation of the organic functional layer and further conducted via light irradiation after the formation of the organic functional layer.

8. The method for producing an organic electroluminescence element according to the aspect 7 having the following features. Patterning shapes of the light emitting unit are not the same in a stacking direction. Among the N sets of light emitting units, in a second to Nth light emitting units excluding a first light emitting unit placed closest to an electrode at a light emitting surface side, the patterning of the organic functional layer during the patterning process is conducted via using a mask during formation of the organic functional layer. Alternatively, such patterning is conducted using a mask during formation of the organic functional layer and further conducted via light irradiation after the formation of the organic functional layer.

9. The method for producing an organic electroluminescence element according to the aspect 7 or 8 having the following feature. The organic functional layer subjected to patterning using a mask during formation of the organic functional layer includes a hole injection layer.

10. The method for producing an organic electroluminescence element according to the aspect 9 having the following feature. The organic functional layer subjected to patterning using a mask during formation of the organic functional layer is the hole injection layer.

11. The method for producing an organic electroluminescence element according to the aspect 10 having the following feature. The hole injection layer has a thickness of from 2 to 50 nm.

12. The method for producing an organic electroluminescence element according to the aspect 10 or 11 having the following features. Each of the N sets of light emitting units includes a hole transport layer adjacent to the hole injection layer, and the hole transport layer has a thickness of from 15 to 200 nm.

13. An organic electroluminescence module including the organic electroluminescence element according to any one of the aspects 1 to 6.

14. The organic electroluminescence module according to the aspect 13, further including a polarizer, a half-mirror, or a black filter on a surface of the supporting substrate of the organic electroluminescence element.

The above aspects of the present invention provide an organic electroluminescence element eliminating uneven light emission and capable of changing a light emitting pattern, a method for producing the organic electroluminescence element, and an organic electroluminescence module including the organic electroluminescence element.

### BRIEF DESCRIPTION OF THE DRAWINGS

FIG. 1 is a schematic cross-sectional view illustrating an organic electroluminescence element of the present invention.

FIG. 2A is a plane view illustrating a pattern shape of an organic functional layer included in a first light emitting unit.

FIG. 2B is a plane view illustrating a pattern shape of an organic functional layer included in a second light emitting unit.

FIG. 3 is a plane view of a mask plate used during patterning in a step of irradiating the first and second light emitting units with light.

FIG. 4A is a plane view illustrating a shape of patterning of an organic functional layer included in a first light emitting unit.

FIG. 4B is a plane view illustrating a pattern shape of an organic functional layer included in a second light emitting unit.

FIG. 5A is a plane view of a mask plate used during patterning in a step of irradiating the first and second light emitting units with light.

FIG. 5B is a plane view of a mask plate used during patterning in a step of irradiating only the first light emitting unit with light.

FIG. 6A is a plane view illustrating a pattern shape of an organic functional layer included in a first light emitting unit.

FIG. 6B is a plane view illustrating a pattern shape of an organic functional layer included in a second light emitting unit.

FIG. 7A is a plane view of a mask plate used during patterning in a step of irradiating the first and second light emitting units with light.

FIG. 7B is a plane view of a mask plate used during patterning in a step of irradiating only the first light emitting unit with light.

FIG. 8 is a schematic cross-sectional view illustrating an organic EL module.

FIGS. 9A to 9G respectively illustrate a configuration of a light emitting unit.

### DETAILED DESCRIPTION OF THE PRESENT INVENTION

Hereinafter, embodiments of the present invention will be described in detail referring to the attached drawings.

Note that a phrase of “n to m” described herein for defining a range of numerical values means that both values “n” and “m” are included in the range as a lower limit and an upper limit, respectively.

First, the respective components of an organic electroluminescence element (hereinafter, appropriately referred to as an “organic EL element”) of the present invention will be described in detail.

<<Layer Structure of Organic EL Element>>

Hereinafter, preferable layer structures of the organic EL elements of the present invention will be exemplified more specifically. However, the present invention is not limited to these examples.

(I) Anode/first light emitting unit/intermediate metal layer/second light emitting unit/cathode

(II) Anode/first light emitting unit/first intermediate metal layer/second light emitting unit/second intermediate metal layer/third light emitting unit/cathode

(I-1) Anode/white light emitting unit/intermediate metal layer/white light emitting unit/cathode

(II-1) Anode/white light emitting unit/first intermediate metal layer/white light emitting unit/second intermediate metal layer/white light emitting unit/cathode

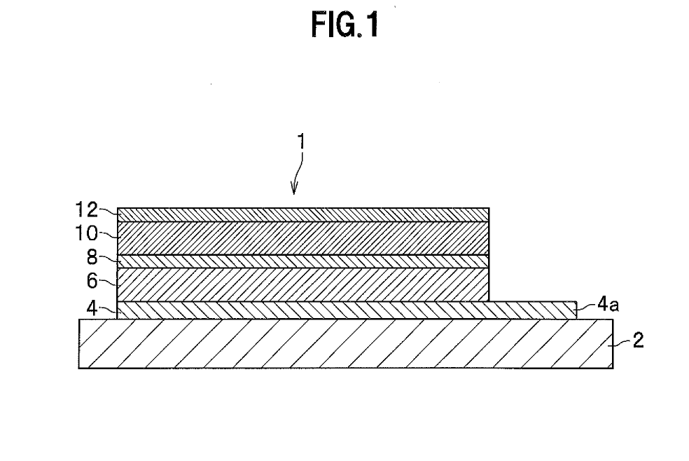

FIG. 1 shows an organic EL element having the above structure (I), as an example thereof according to the present invention.

As shown in FIG. 1, the organic EL element 1 includes a supporting substrate 2, an anode 4, a light emitting unit 6, an intermediate metal layer 8, a light emitting unit 10, and a cathode 12 as being stacked in this order.

Herein, the anode 4 is extended to the end side of the supporting substrate 2 to form an extraction electrode 4a.

Note that the anode 4 and the cathode 12 correspond to a first electrode and a second electrode, respectively, set forth in the entire description herein.

Here, the number of light emitting units is, but is not particularly limited to, 2 or more. In view of productive efficiency, the number is preferably set from 2 to 10, and more preferably from 2 to 3. Note that if the number of light emitting units is N (where N represents an integer of 2 or more), the number of intermediate metal layers is (N−1).

Next, preferable layer structures of the light emitting units will be exemplified more specifically, hereinafter. However, the present invention is not limited to these examples.

(i) Hole injection and transport layer/light emitting layer/electron injection and transport layer

(ii) Hole injection and transport layer/light emitting layer/hole blocking layer/electron injection and transport layer

(iii) Hole injection and transport layer/electron blocking layer/light emitting layer/hole blocking layer/electron injection and transport layer

(iv) Hole injection layer/hole transport layer/light emitting layer/electron transport layer/electron injection layer

(v) Hole injection layer/hole transport layer/light emitting layer/hole blocking layer/electron transport layer/electron injection layer

(vi) Hole injection layer/hole transport layer/electron blocking layer/light emitting layer/hole blocking layer/electron transport layer/electron injection layer

As used herein, different materials may be combined to construct each light emitting unit. However, except for a light emitting layer included in a light emitting unit, preferably the same layers or materials may be used to construct the light emitting unit. More preferably, the number of the light emitting layers may be the same. This is advantageous in view of the costs and quality control because the number of materials can be reduced in the production. Further, this is also advantageous in view of the productive efficiency because a deposition chamber used in a vapor deposition process can be easily shared among different types of the light emitting units.

Accordingly, on the same grounds as mentioned above, it is most preferable that the structures and materials of all the layers including a light emitting layer are the same.

A known method for forming a thin film may be applied to the formation of each layer by which a light emitting unit is constructed. The method includes, for example, a vacuum vapor deposition method, a spin coating method, casting, an LB (Langmuir-Blodgett), an ink jet method, spraying, printing, and a slot-type coater method. Each layer may be formed by the above thin film formation methods.

Next, the respective layers constructing the organic EL element of the present invention will be described hereinafter.

<Intermediate Metal Layer (8)>

An intermediate metal layer of the present invention is optically transparent and arranged between two light emitting units.

The intermediate metal layer may have a so called pinhole, that is, such a layer may be in a state that almost no metal is deposited at a part of fine regions. Further, the intermediate metal layer may be formed as mesh in a surface direction. Alternatively, the intermediate metal layer may be formed in an island structure (or spotted).

A metal with a work function of 3.0 eV or less may be used for an intermediate metal layer of the present invention.

Examples of the material used for the intermediate metal layer include calcium (with a work function of 2.87 eV; a melting point of 1112.2 K), lithium (with a work function of 2.9 eV; a melting point of 453.7 K), sodium (with a work function of 2.75 eV; a melting point of 371 K), potassium (with a work function of 2.3 eV; a melting point of 336.9 K), cesium (with a work function of 2.14 eV; a melting point of 301.6 K), rubidium (with a work function of 2.16 eV; a melting point of 312.1 K), barium (with a work function of 2.7 eV; a melting point of 998.2 K), and strontium (with a work function of 2.59 eV; a melting point of 1042.2 K). Among them, preferable materials have a melting point of 400 K or higher under ordinary pressure and have little risk of losing performance of an organic EL element under a high temperature environment. Such examples include lithium, calcium, barium, and strontium.

The intermediate metal layer has a thickness of preferably from 0.6 to 5 nm, more preferably from 0.8 to 3 nm, and still more preferably from 0.8 to 2 nm.

When the intermediate metal layer has a thickness of 5 nm or less, it is possible to suppress a decrease in efficiency of an organic EL element via suppressing the light absorption of a metallic material used, thereby preventing deterioration in storage and/or operation stability.

Meanwhile, when the intermediate metal layer has a thickness of 0.6 nm or more, the organic EL element has better performance stability. That is, particularly, the performance little fluctuates in a relatively early stage, after production of the element.

Note that as used herein, the phrase “thickness of an intermediate metal layer” is defined as an “average thickness” as calculated by dividing a mass of film deposition per unit area of an intermediate metal layer by a material density. Accordingly, the thickness of any portion of the intermediate metal layer may be thicker or thinner than the “average thickness”.

In the present invention, it is preferable to decrease conductivity of the intermediate metal layer in a surface direction without decreasing conductivity thereof in a voltage application direction. Therefore, at least one side of the intermediate metal layer facing a light emitting unit is preferably formed as a non-flat surface more than both sides are formed as completely flat surfaces. As used herein, the phrase “an intermediate metal layer has a non-flat surface” means that the intermediate metal layer has a shape of mesh or island structure in a surface direction.

In addition, a layer adjacent to an intermediate metal layer at the anode side is preferably formed by depositing a single kind of organic compound. Under this condition, the production process becomes simpler thereby allowing the process management easier. Further, this may also reduce a risk of performance variation resulting from use of a plurality of materials. On top of that, it is possible to obtain superior long-term or high-temperature storage stability and long-term operation stability. Thus, it is preferable to apply the above condition.

An intermediate metal layer is interposed between a light emitting unit positioned at the cathode side and a light emitting unit positioned at the anode side. Herein, layers adjacent to the intermediate metal layer preferably has a function capable of transferring charge from each light emitting unit and easily injecting the charge into each light emitting unit through the intermediate metal layer.

The layer having such a function is preferably formed as a mixed layer produced by doping a charge transporting organic material and an inorganic material and/or an organometallic complex so as to increase the charge transporting. Such an inorganic material and/or an organometallic complex is capable of oxidizing or reducing the foregoing organic material, or capable of forming a charge transfer complex with the foregoing organic material.

<Light-Emitting Layer>

A light emitting layer preferably contains a host compound and a light emitting dopant.

The light emitting dopant included in the light emitting layer may be contained at a uniform concentration, or have concentration distribution in a thickness direction within the light emitting layer.

The thickness of each light emitting layer included in each light emitting unit is not particularly limited. However, in view of uniformity of a film formed, prevention of application of an unnecessary high-voltage during light emission, and increased stability of an emission color depending on a driving current, the thickness is adjusted to preferably in a range from 5 to 200 nm, and more preferably from 10 to 100 nm.

Next, a phosphorescent host compound and a phosphorescent light emitting dopant included in a light emitting layer will be described in detail.

(1) Phosphorescent Host Compound

The structure of a phosphorescent host compound used in the present invention is not particularly limited. The representative phosphorescent host compounds include: carbazole derivatives; triarylamine derivatives; aromatic boranes; nitrogen-containing heterocyclic compounds; thiophene derivatives; furan derivatives; and oligoarylene compounds. Also included are carboline derivatives and diazacarbazole derivatives (here, the diazacarbazole derivative is a compound in which at least one carbon atom of a hydrocarbon ring included in a carboline ring system of a carboline derivative is replaced with a nitrogen atom).

Here, a single compound may be used for the phosphorescent host compound, or a plurality of the compounds may be combined to be used for the phosphorescent host compound.

A phosphorescent host compound used for a light emitting layer of the present invention is preferably represented by the following general formula (a):

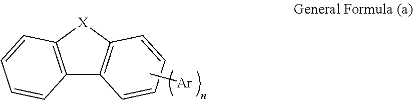

In the general formula (a), “X” represents NR′, O, S, CR′R″, or SiR′R″. R′ and R″ each independently represents hydrogen or a substituent. “Ar” represents an aromatic ring. The “n” represents an integer of from 0 to 8.

Examples of the substituent represented by R′ and R″ in the “X” of the general formula (a) include: alkyls (e.g., methyl, ethyl, propyl, isopropyl, tert-butyl, pentyl, hexyl, octyl, dodecyl, tridecyl, tetradecyl, pentadecyl); cycloalkyls (e.g., cyclopentyl, cyclohexyl); alkenyls (e.g., vinyl, allyl, 1-propenyl, 2-butenyl, 1,3-butadienyl, 2-pentenyl, isopropenyl); alkynyls (e.g., ethynyl, propargyl); aromatic hydrocarbons (also referred to as an aromatic carbon ring system or aryl such as phenyl, p-chlorophenyl, mesityl, tolyl, xylyl, naphthyl, anthryl, azulenyl, acenaphthenyl, fluorenyl, phenanthryl, indenyl, pyrenyl, biphenylyl); aromatic heterocycles (e.g., furyl, thienyl, pyridyl, pyridazinyl, pyrimidinyl, pyrazinyl, triazinyl, imidazolyl, pyrazolyl, thiazolyl, quinazolinyl, carbazolyl, carbolinyl, diazacarbazolyl (a compound in which any one of carbon atoms constituting a carboline ring of a carbolinyl group is replaced with a nitrogen atom.); heterocycles (e.g., pyrrolidyl, imidazolidyl, morpholyl, oxazolidinyl); alkoxys (e.g., methoxy, ethoxy, propyloxy, pentyloxy, hexyloxy, octyloxy, dodecyloxy); cycloalkoxys (e.g., cyclopentyloxy, cyclohexyloxy); aryloxys (e.g., phenoxy, naphthyloxy); alkylthios (e.g., methylthio, ethylthio, propylthio, pentylthio, hexylthio, octylthio, dodecylthio); cycloalkylthios (e.g., cyclopentylthio, cyclohexylthio); arylthios (e.g., phenylthio, naphthylthio); alkoxycarbonyls (e.g., methyloxycarbonyl, ethyloxycarbonyl, butyloxycarbonyl, octyloxycarbonyl, dodecyloxycarbonyl); aryloxycarbonyls (e.g., phenyloxycarbonyl, naphthyloxycarbonyl); sulfamoyls (e.g., aminosulfonyl, methylaminosulfonyl, dimethylaminosulfonyl, butylaminosulfonyl, hexylaminosulfonyl, cyclohexylaminosulfamoyl, octylaminosulfonyl, dodecylaminosulfonyl, phenylaminosulfonyl, naphthylaminosulfonyl, 2-pyridylaminosulfonyl); acyls (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, pyridylcarbonyl); acyloxys (e.g., acetyloxy, ethylcarbonyloxy, butylcarbonyloxy, octylcarbonyloxy, dodecylcarbonyloxy, phenylcarbonyloxy); amidos (e.g., methylcarbonylamino, ethylcarbonylamino, dimethylcarbonylamino, propylcarbonylamino, pentylcarbonylamino, cyclohexylcarbonylamino, 2-ethylhexylcarbonylamino, octylcarbonylamino, dodecylcarbonylamino, phenylcarbonylamino, naphthylcarbonylamino); carbamoyls (e.g., aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, 2-pyridylaminocarbonyl); ureides (e.g., methylureide, ethylureide, pentylureide, cyclohexylureide, octylureide, dodecylureide, phenylureide, naphthylureide, 2-pyridylaminoureide); sulfinyls (e.g., methylsulfinyl, ethylsulfinyl, butylsulfinyl, cyclohexylsulfinyl, 2-ethylhexylsulfinyl, dodecylsulfinyl, phenylsulfinyl, naphthylsulfinyl, 2-pyridylsulfinyl); alkylsulfonyls (e.g., methylsulfonyl, ethylsulfonyl, butylsulfonyl, cyclohexylsulfonyl, 2-ethylhexylsulfonyl, dodecylsulfonyl); arylsulfonyls or heteroarylsulfonyls (e.g., phenylsulfonyl, naphthylsulfonyl, 2-pyridylsulfonyl); aminos (e.g., amino, ethylammino, dimethylamino, butylamino, cyclopentylamino, 2-ethylhexylamino, dodecylamino, anilino, naphthylamino, 2-pyridylamino); halogens (e.g., fluorine, chlorine, bromine); fluoro hydrocarbons (e.g., fluoromethyl, trifluoromethyl, pentafluoroethyl, pentafluorophenyl); cyanos; nitros; hydroxyls; mercaptos; silyls (e.g., trimethylsilyl, triisopropylsilyl, triphenylsilyl, phenyldiethylsilyl); and phosphonos.

Those substituents may be optionally further substituted with the above substituents. In addition, a plurality of the substituents may be bonded each other to form a ring system.

In the general formula (a), the “X” is preferably NR′ or O and the R′ is more preferably aromatic hydrocarbon or aromatic heterocycle.

In the general formula (a), examples of an aromatic ring represented by the “Ar” include an aromatic hydrocarbon ring or an aromatic heterocyclic ring.

The aromatic ring represented by the “Ar” may be either a monocyclic ring or a condensed ring. Further, the aromatic ring may be unsubstituted or may have a substituent represented by the above R′ and R″.

Examples of the aromatic hydrocarbon ring represented by the “Ar” in the general formula (a) include a benzene ring, a biphenyl ring, a naphthalene ring, an azulene ring, an anthracene ring, a phenanthrene ring, a pyrene ring, a chrysene ring, a naphthacene ring, a triphenylene ring, o-terphenyl ring, m-terphenyl ring, p-terphenyl ring, an acenaphthene ring, a coronene ring, a fluorene ring, a fluoranthene ring, a naphthacene ring, a pentacene ring, a perylene ring, a pentaphene ring, a picene ring, a pyrene ring, a pyranthrene ring, and an anthanthrene ring.

Examples of the aromatic heterocyclic ring represented by the “Ar” in the general formula (a) include a furan ring, a dibenzofuran ring, a thiophene ring, an oxazole ring, a pyrrole ring, a pyridine ring, a pyridazine ring, a pyrimidine ring, a pyrazine ring, a triazine ring, a benzoimidazole ring, an oxadiazole ring, a triazole ring, an imidazole ring, a pyrazole ring, a thiazole ring, an indole ring, an indazole ring, a benzoimidazole ring, a benzothiazole ring, a benzoxazole ring, a quinoxaline ring, a quinazoline ring, a cinnoline ring, a quinoline ring, an isoquinoline ring, a phthalazine ring, a naphthyridine ring, a carbazole ring, a carboline ring, and a diazacarbazole ring (a ring in which one of carbon atoms of a hydrocarbon ring constituting a carboline ring is substituted with a nitrogen atom).

Among them as the aromatic ring represented by the “Ar” in the general formula (a), preferred are a carbazole ring, a carboline ring, a dibenzofuran ring, and a benzene ring. More preferred are a carbazole ring, a carboline ring, and a benzene ring. Still more preferred is a benzene ring having a substituent. Most preferred is a benzene ring substituted with a carbazolyl group.

In addition, as the aromatic ring represented by the “Ar” in the general formula (a), preferable embodiments include the following condensed rings each having three or more rings. Specific examples of such an aromatic hydrocarbon condensed ring in which three or more rings are condensed include a naphthacene ring, an anthracene ring, a tetracene ring, a pentacene ring, a hexacene ring, a phenanthrene ring, a pyrene ring, a benzopyrene ring, benzoazulene ring, a chrysene ring, a benzochrysene ring, an acenaphthene ring, an acenaphthylene ring, a triphenylene ring, a coronene ring, a benzocoronene ring, a hexabenzocoronene ring, a fluorene ring, benzofluorene ring, a fluoranthene ring, a perylene ring, a naphthperylene ring, a pentabenzoperylene ring, benzoperylene ring, a pentaphene ring, a picene ring, a pyranthrene ring, a coronene ring, a naphthcoronene ring, an ovalene ring, and an anthanthrene ring.

Specific examples of the aromatic heterocyclic ring in which three or more rings are condensed include an acridine ring, a benzoquinoline ring, a carbazole ring, a carboline ring, a phenazine ring, a phenanthridine ring, a phenanthroline ring, a carboline ring, a cycladine ring, a quindoline ring, a tepenidine ring, a quinindoline ring, a triphenodithiazine ring, a triphenodioxazine ring, a phenanthrazine ring, an. anthrazine ring, a perimidine ring, a diazacarbazole ring (a ring in which one of carbon atoms of a hydrocarbon ring constituting a carboline ring is substituted with a nitrogen atom), a phenanthroline ring, a dibenzofuran ring, a dibenzothiophene ring, a naphthofuran ring, a naphthothiophene ring, a benzofuran ring, a benzothiophene ring, a naphthodifuran ring, a naphthodithiophene ring, an anthrafuran ring, an anthradifuran ring, an anthrathiophene ring, an anthradithiophene ring, a thianthrene ring, a phenoxathiin ring, and a thiophanthrene (naphthothiophene) ring.

In addition, in the general formula (a), the “n” represents an integer of from 0 to 8. Preferred is an integer of 0 to 2. When the “X” is O or S, preferred is 1 or 2.

The following describes specific examples of the phosphorescent host compound represented by the general formula (a). However, the examples are not limited to the following.

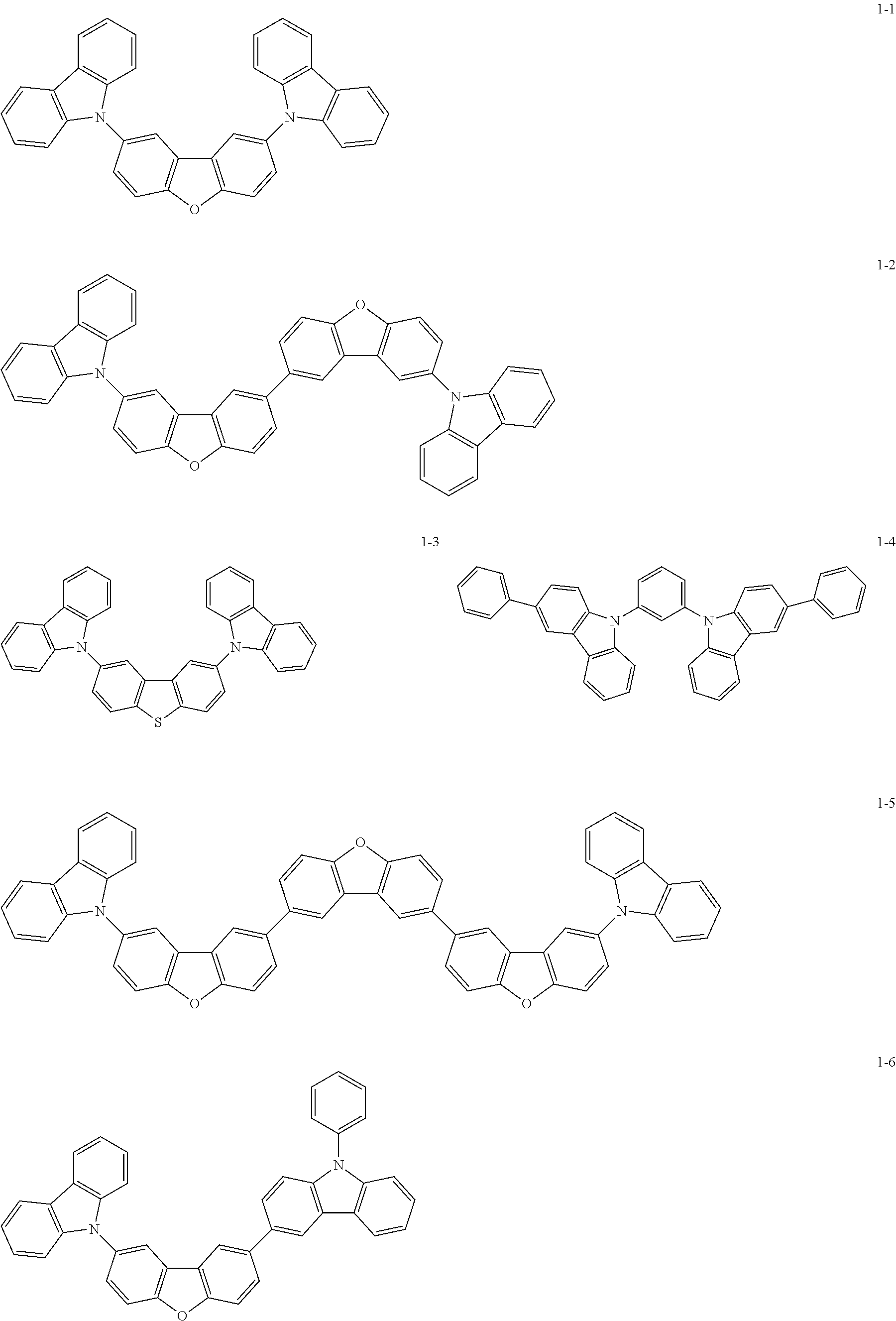

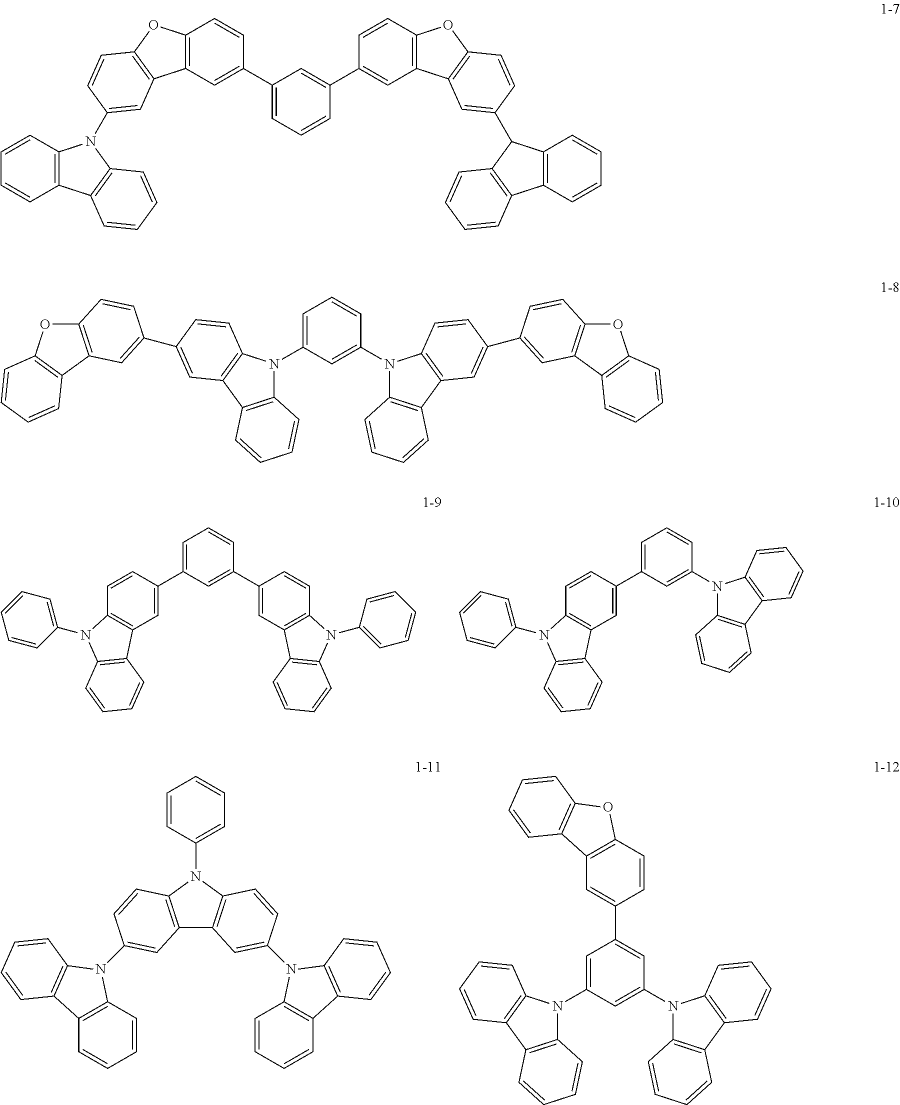

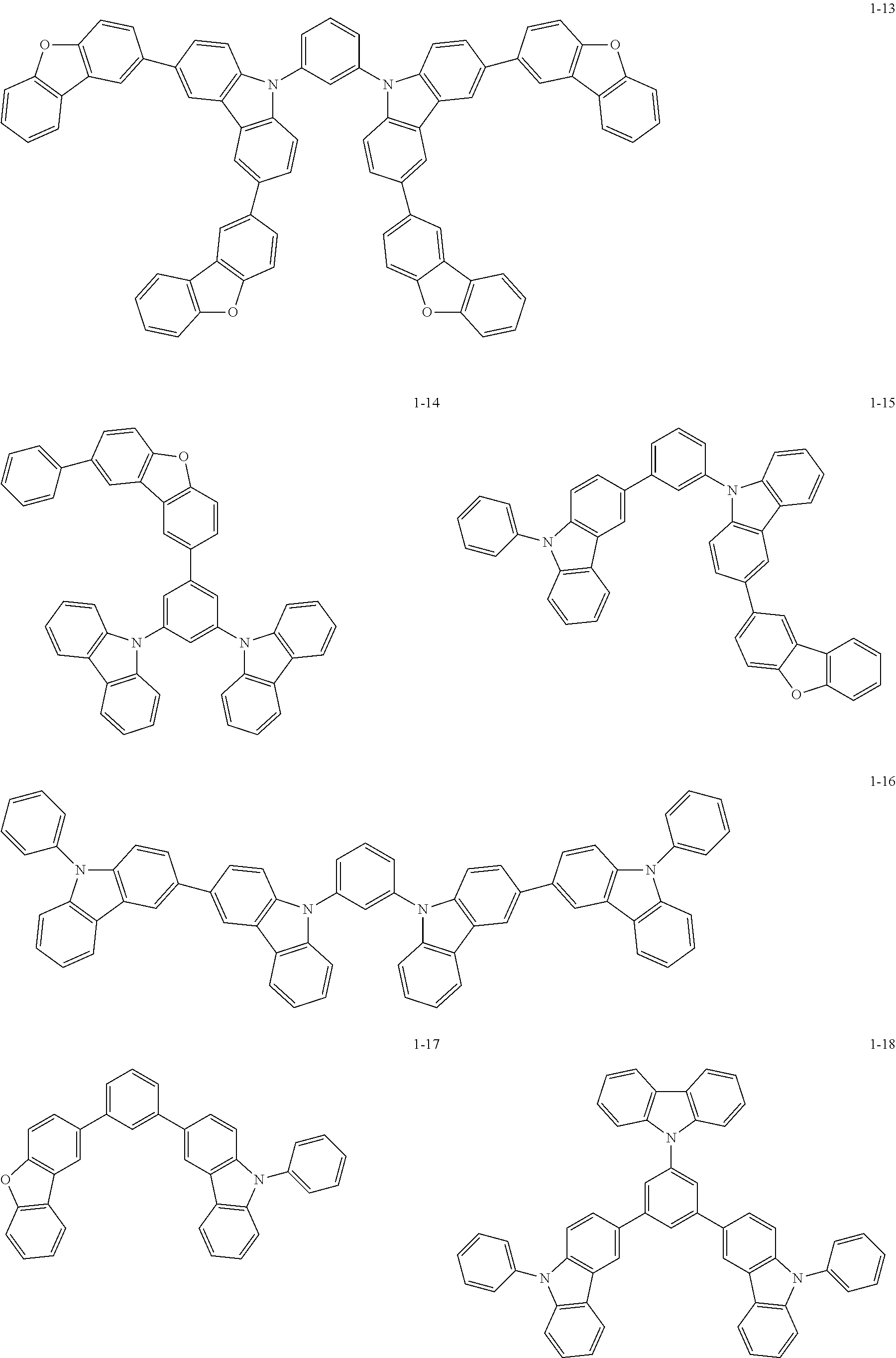

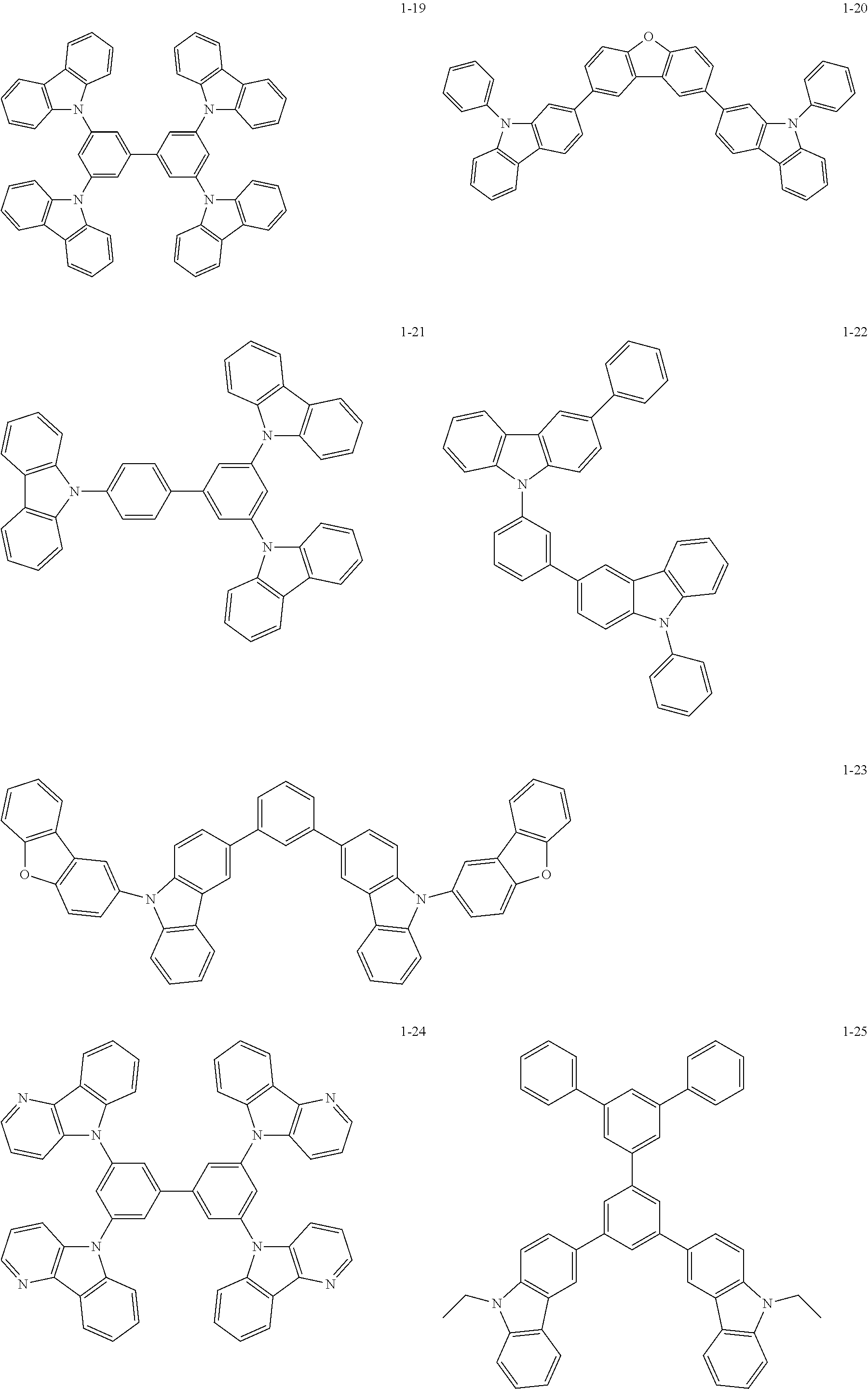

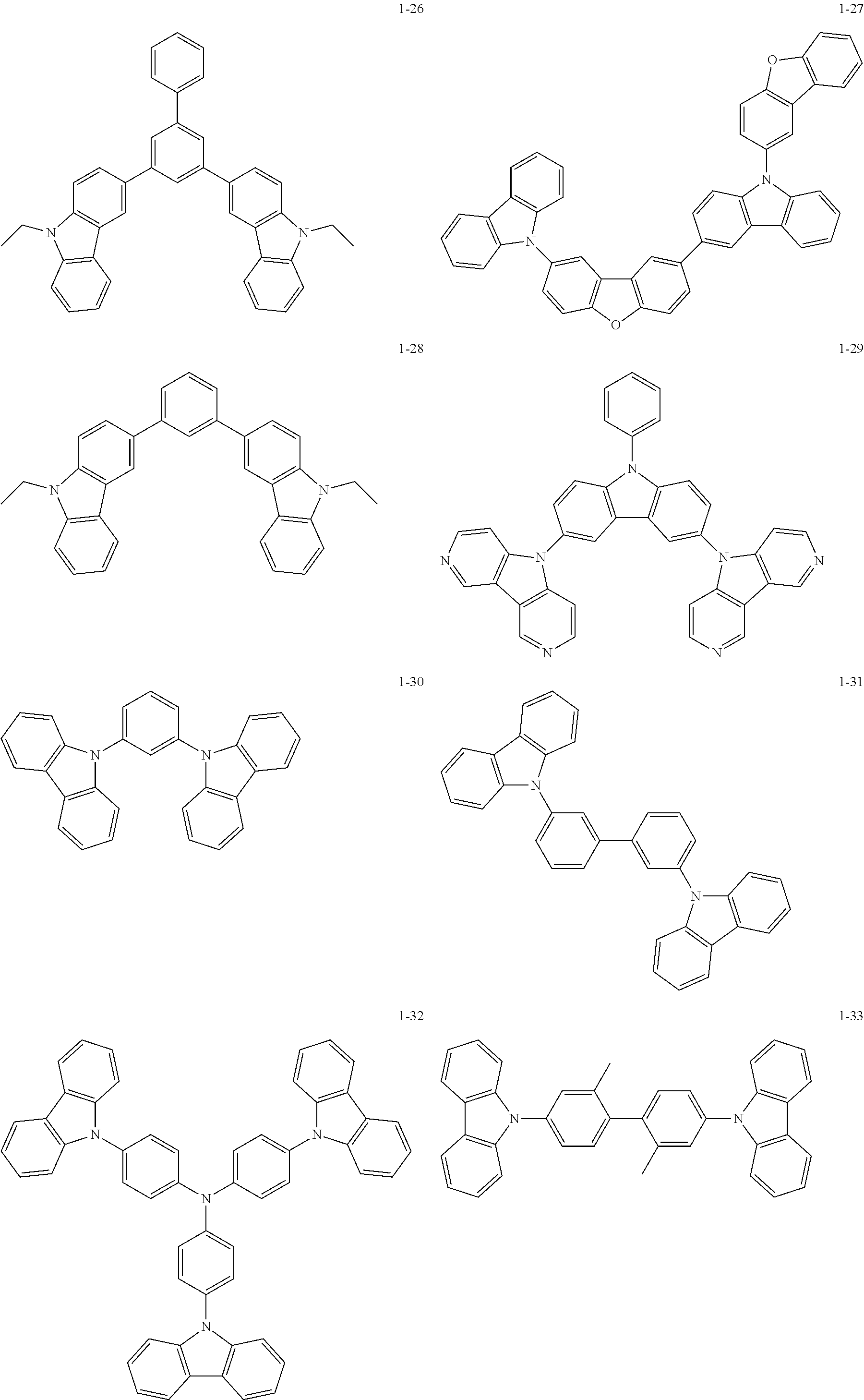

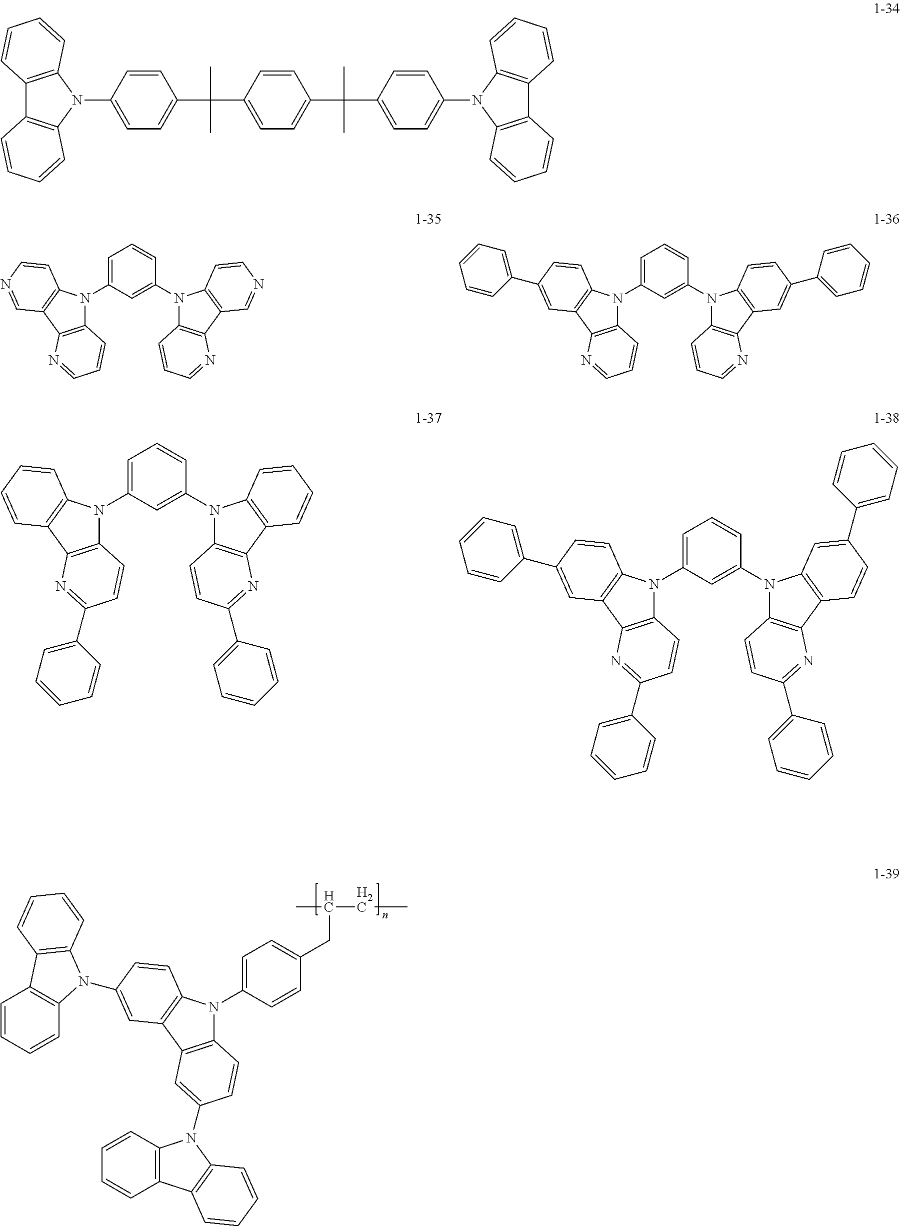

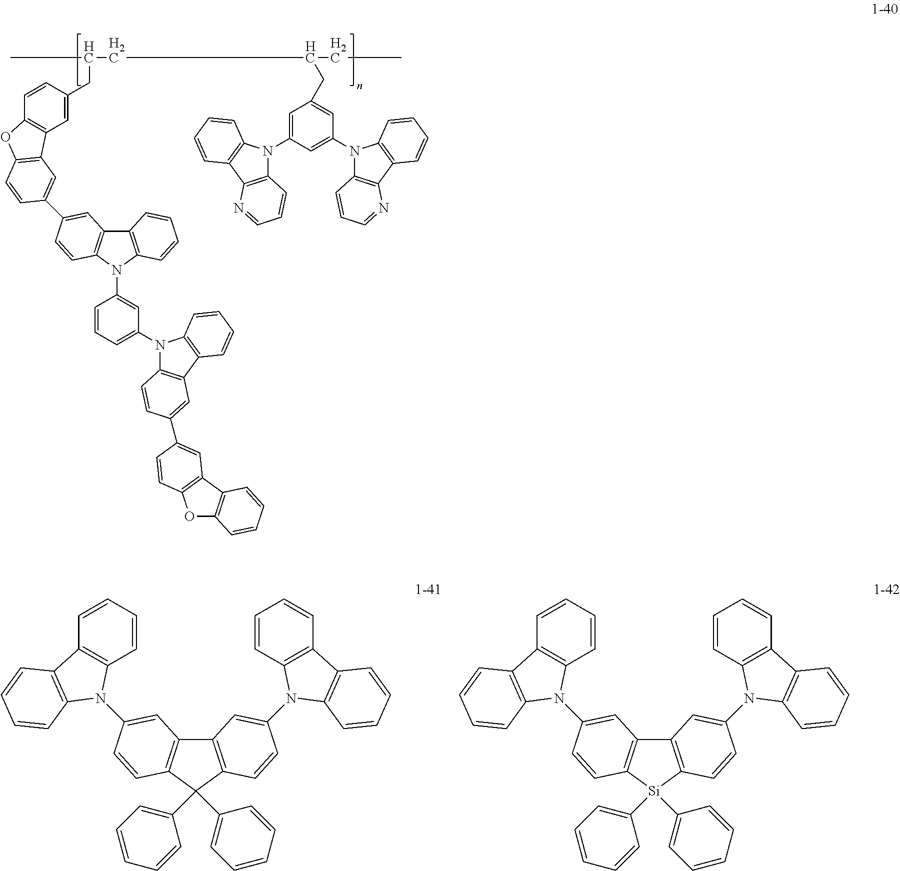

In addition, a phosphorescent host compound used in an embodiment of the present invention may be a low-molecular-weight compound, a high-molecular-weight compound having a repeating unit, or a low-molecular-weight compound (a vapor deposition polymerizable luminescent host compound) having a polymerizable group such as a vinyl group and/or an epoxy group.

Preferable phosphorescent host compounds are compounds having hole and electron transport capacity and a high Tg (a glass transition temperature) without making the wavelength of phosphorescent light become longer. In an embodiment of the present invention, preferred is a compound having a glass transition temperature of 90° C. or higher. More preferred is a compound having a glass transition temperature of 130° C. or higher because excellent characteristics can be obtained.

As used herein, the glass transition temperature (Tg) may be calculated by a method according to JIS K 7121 using DSC (Differential Scanning Colorimetry).

In addition, in an embodiment of the present invention, conventionally known host compounds may be used.

Specific examples of the conventionally known host compounds that can be suitably used include compounds listed in the following literatures. Examples include JP2001-257076A, JP2002-308855 A, JP2001-313179 A, JP2002-319491 A, JP2001-357977 A, JP2002-334786 A, JP2002-8860 A, JP2002-334787 A, JP2002-15871 A, JP2002-334788 A, JP2002-43056 A, JP2002-334789 A, JP2002-75645 A, JP2002-338579 A, JP2002-105445 A, JP2002-343568 A, JP2002-141173 A, JP2002-352957 A, JP2002-203683 A, JP2002-363227 A, JP2002-231453 A, JP2003-3165 A, JP2002-234888 A, JP2003-27048 A, JP2002-255934 A, JP2002-260861 A, JP2002-280183 A, JP2002-299060 A, JP2002-302516 A, JP2002-305083 A, JP2002-305084 A, and JP2002-308837 A.

In an embodiment of the present invention, each light-emitting layer of each light emitting unit may have a different phosphorescent host compound. However, use of the same compound is preferable in view of productive efficiency and process management.

In addition, it is preferable for the phosphorescent host compound to have a lowest excited triplet energy (T1) of more than 2.7 eV because a higher luminance efficiency can be achieved.

As used herein, the term “lowest excited triplet energy” refers to the peak energy of a luminescence band corresponding to a lowest vibration interband transition of a phosphorescence spectrum as observed at a liquid nitrogen temperature under conditions in which a host compound is dissolved in a solvent.

(2) Phosphorescent Dopant

Phosphorescent dopants which can be used in embodiments of the present invention may be selected from publicly known compounds. Examples include a complex compound containing any of group 8 to 10 metals of the periodic table of elements. It is possible to preferably select from an iridium compound, an osmium compound, a platinum compound such as a platinum complex, and a rare-earth element complex. Among them, most preferred is an iridium compound.

When a white-light-emitting organic EL element is produced, a phosphorescent material is preferably used as a luminescent material that can emit light with a color range of at least green, yellow, and red.

(Substructure Represented by General Formulae (A) to (C))

In addition, when a blue phosphorescent dopant is used as a phosphorescent dopant, the dopant may be appropriately selected from known dopants that can be used for a light-emitting layer of an organic EL element. However, preferred is a dopant having at least one substructure selected from the following general formulae (A) to (C).

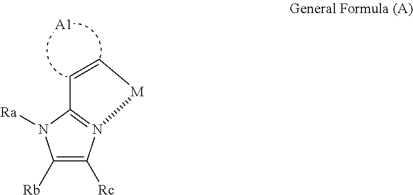

In the general formula (A), the “Ra” represents hydrogen, an aliphatic group, an aromatic group, or a heterocyclic group. The “Rb” and “Rc” each independently represent hydrogen or a substituent. The “A1” represents a residue required to form an aromatic ring or an aromatic heterocyclic ring. The “M” represents Ir or Pt.

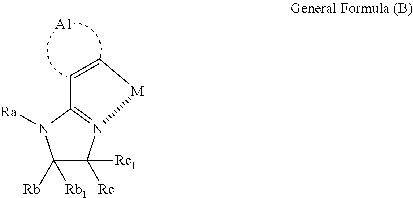

In the general formula (B), the “Ra” represents hydrogen, an aliphatic group, an aromatic group, or a heterocyclic group. The “Rb”, “Rc”, “Rb₁”, and “Rc₁” each independently represent hydrogen or a substituent. The “A1” represents a residue required to form an aromatic ring or an aromatic heterocyclic ring. The “M” represents Ir or Pt.

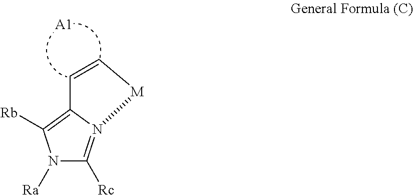

In the general formula (C), the “Ra” represents hydrogen, an aliphatic group, an aromatic group, or a heterocyclic group. The “Rb” and “Rc” each independently represent hydrogen or a substituent. The “A1” represents a residue required to form an aromatic ring or an aromatic heterocyclic ring. The “M” represents Ir or Pt.

Examples of the aliphatic group represented by the “Ra” in the general formulae (A) to (C) include alkyls (e.g., methyl, ethyl, propyl, butyl, pentyl, isopentyl, 2-ethyl-hexyl, octyl, undecyl, dodecyl, tetradecyl) and cycloalkyls (e.g., cyclopentyl, cyclohexyl). Examples of the aromatic group include phenyl, tolyl, azulenyl, anthranil, phenanthryl, pyrenyl, chrysenyl, naphthacenyl, o-terphenyl, m-terphenyl, p-terphenyl, acenaphthenyl, coronenyl, fluorenyl, and perylenyl. Examples of the heterocyclic group include pyrrolyl, indolyl, furyl, thienyl, imidazolyl, pyrazolyl, indolizinyl, quinolinyl, carbazolyl, indolinyl, thiazolyl, pyridyl, pyridazinyl, thiadiazinyl, oxadiazolyl, benzoquinolinyl, thiadiazolyl, pyrrolothiazolyl, pyrrolopyridazinyl, tetrazolyl, oxazolyl, and chromanyl.

These groups may have a substituent represented by the “R′” and “R″” in the general formula (a)

Examples of the substituent represented by the “Rb”, “Rc”, “Rb₁”, or “Rc₁” in the general formulae (A) to (C) include: alkyls (e.g., methyl, ethyl, propyl, isopropyl, tert-butyl, pentyl, hexyl, octyl, dodecyl, tridecyl, tetradecyl, pentadecyl); cycloalkyls (e.g., cyclopentyl, cyclohexyl); alkenyls (e.g., vinyl, allyl); alkynyls (e.g., ethynyl, propargyl); aryls (e.g., phenyl, naphthyl); aromatic heterocycles (e.g., furyl, thienyl, pyridyl, pyridazinyl, pyrimidinyl, pyrazinyl, triazinyl, imidazolyl, pyrazolyl, thiazolyl, quinazolinyl, phthalazinyl); heterocycles (e.g., pyrrolidyl, imidazolidyl, morpholyl, oxazolidinyl); alkoxys (e.g., methoxy, ethoxy, propyloxy, pentyloxy, hexyloxy, octyloxy, dodecyloxy); cycloalkoxys (e.g., cyclopentyloxy, cyclohexyloxy); aryloxys (e.g., phenoxy, naphthyloxy); alkylthios (e.g., methylthio, ethylthio, propylthio, pentylthio, hexylthio, octylthio, dodecylthio); cycloalkylthios (e.g., cyclopentylthio, cyclohexylthio); arylthios (e.g., phenylthio, naphthylthio); alkoxycarbonyls (e.g., methyloxycarbonyl, ethyloxycarbonyl, butyloxycarbonyl, octyloxycarbonyl, do decyloxycarbonyl); aryloxycarbonyls (e.g., phenyloxycarbonyl, naphthyloxycarbonyl); sulfamoyls (e.g., aminosulfonyl, methylaminosulfonyl, dimethylaminosulfonyl, butylaminosulfonyl, hexylaminosulfonyl, cyclohexylaminosulfamoyl, octylaminosulfonyl, dodecylaminosulfonyl, phenylaminosulfonyl, naphthylaminosulfonyl, 2-pyridylaminosulfonyl); acyls (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, pyridylcarbonyl); acyloxys (e.g., acetyloxy, ethylcarbonyloxy, butylcarbonyloxy, octylcarbonyloxy, dodecylcarbonyloxy, phenylcarbonyloxy); amidos (e.g., methylcarbonylamino, ethylcarbonylamino, dimethylcarbonylamino, propylcarbonylamino, pentylcarbonylamino, cyclohexylcarbonylamino, 2-ethylhexylcarbonylamino, octylcarbonylamino, dodecylcarbonylamino, phenylcarbonylamino, naphthylcarbonylamino); carbamoyls (e.g., aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, 2-pyridylaminocarbonyl); ureides (e.g., methylureide, ethylureide, pentylureide, cyclohexylureide, octylureide, dodecylureide, phenylureide, naphthylureide, 2-pyridylaminoureide); sulfinyls (e.g., methylsulfinyl, ethylsulfinyl, butylsulfinyl, cyclohexylsulfinyl, 2-ethylhexylsulfinyl, dodecylsulfinyl, phenylsulfinyl, naphthylsulfinyl, 2-pyridylsulfinyl); alkylsulfonyls (e.g., methylsulfonyl, ethylsulfonyl, butylsulfonyl, cyclohexylsulfonyl, 2-ethylhexylsulfonyl, dodecylsulfonyl); arylsulfonyls (e.g., phenylsulfonyl, naphthylsulfonyl, 2-pyridylsulfonyl); aminos (e.g., amino, ethylammino, dimethylamino, butylamino, cyclopentylamino, 2-ethylhexylamino, dodecylamino, anilino, naphthylamino, 2-pyridylamino); halogens (e.g., fluorine, chlorine, bromine); fluoro hydrocarbons (e.g., fluoromethyl, trifluoromethyl, pentafluoroethyl, pentafluorophenyl); cyanos; nitros; hydroxyls; mercaptos; and silyls (e.g., trimethylsilyl, triisopropylsilyl, triphenylsilyl, phenyldiethylsilyl).

These substituents may be optionally further substituted with the above substituents

Examples of the aromatic ring represented by the “A1” in the general formulae (A) to (C) include a benzene ring, a biphenyl ring, a naphthalene ring, an azulene ring, an anthracene ring, a phenanthrene ring, a pyrene ring, a chrysene ring, a naphthacene ring, a triphenylene ring, o-terphenyl ring, m-terphenyl ring, p-terphenyl ring, an acenaphthene ring, a coronene ring, a fluorene ring, a fluoranthene ring, a naphthacene ring, a pentacene ring, a perylene ring, a pentaphene ring, a picene ring, a pyrene ring, a pyranthrene ring, and an anthanthrene ring. Examples of the aromatic heterocyclic ring include a furan ring, a thiophene ring, a pyridine ring, a pyridazine ring, a pyrimidine ring, a pyrazine ring, a triazine ring, a benzoimidazole ring, an oxadiazole ring, a triazole ring, an imidazole ring, a pyrazole ring, a thiazole ring, an indole ring, a benzoimidazole ring, a benzothiazole ring, a benzoxazole ring, a quinoxaline ring, a quinazoline ring, a phthalazine ring, a carbazole ring, a carboline ring, and a diazacarbazole ring (a ring in which one of carbon atoms of a hydrocarbon ring constituting a carboline ring is substituted with a nitrogen atom).

In the general formulae (A) to (C), the “M” represents Ir or Pt. Among them, preferred is Ir.

The structures represented by the general formulae (A) to (C) are substructures. When the substructure is converted to a light-emitting dopant having a complete structure, a ligand is required depending on the valence of center metal. Specific examples of such a ligand include: halogens (e.g., fluorine, chlorine, bromine, iodine); aryls (e.g., phenyl, p-chlorophenyl, mesityl, tolyl, xylyl, biphenyl, naphthyl, anthryl, phenanthryl); alkyls (e.g., methyl, ethyl, isopropyl, hydroxyethyl, methoxymethyl, trifluoromethyl, t-butyl); alkyloxys; aryloxys; alkylthios; arylthios; aromatic heterocycles (e.g., furyl, thienyl, pyridyl, pyridazinyl, pyrimidinyl, pyrazinyl, triazinyl, imidazolyl, pyrazolyl, thiazolyl, quinazolinyl, carbazolyl, carbolinyl, phthalazinyl); and substructures without a metal in the general formulae (A) to (C).

A preferable light-emitting dopant is a tris compound whose structure is completed using three substructures represented by the general formulae (A) to (C).

The following describes, as examples, blue phosphorescent dopants having substructures represented by the above general formulae (A) to (C). However, the examples are not limited to the following compounds.

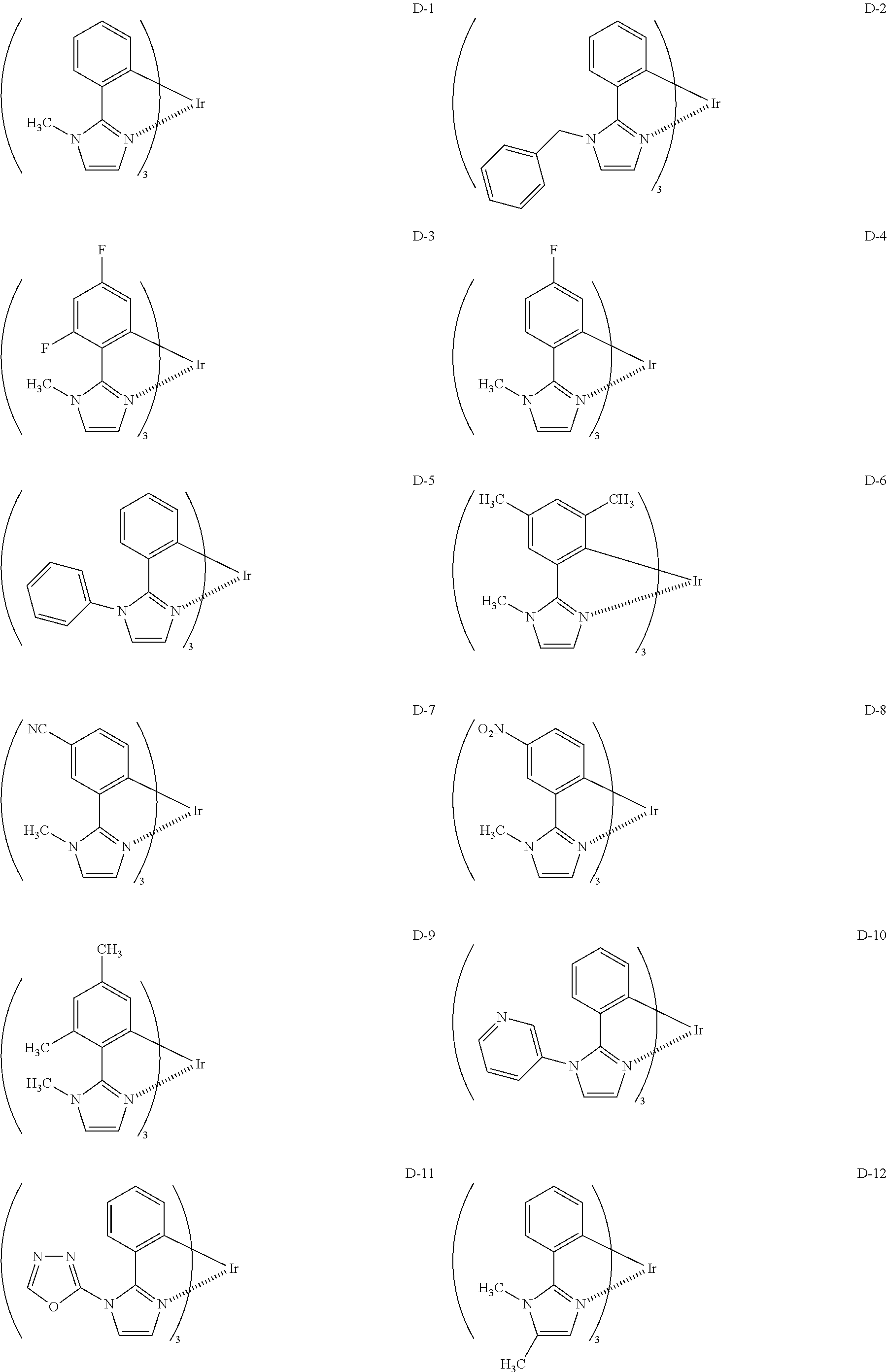

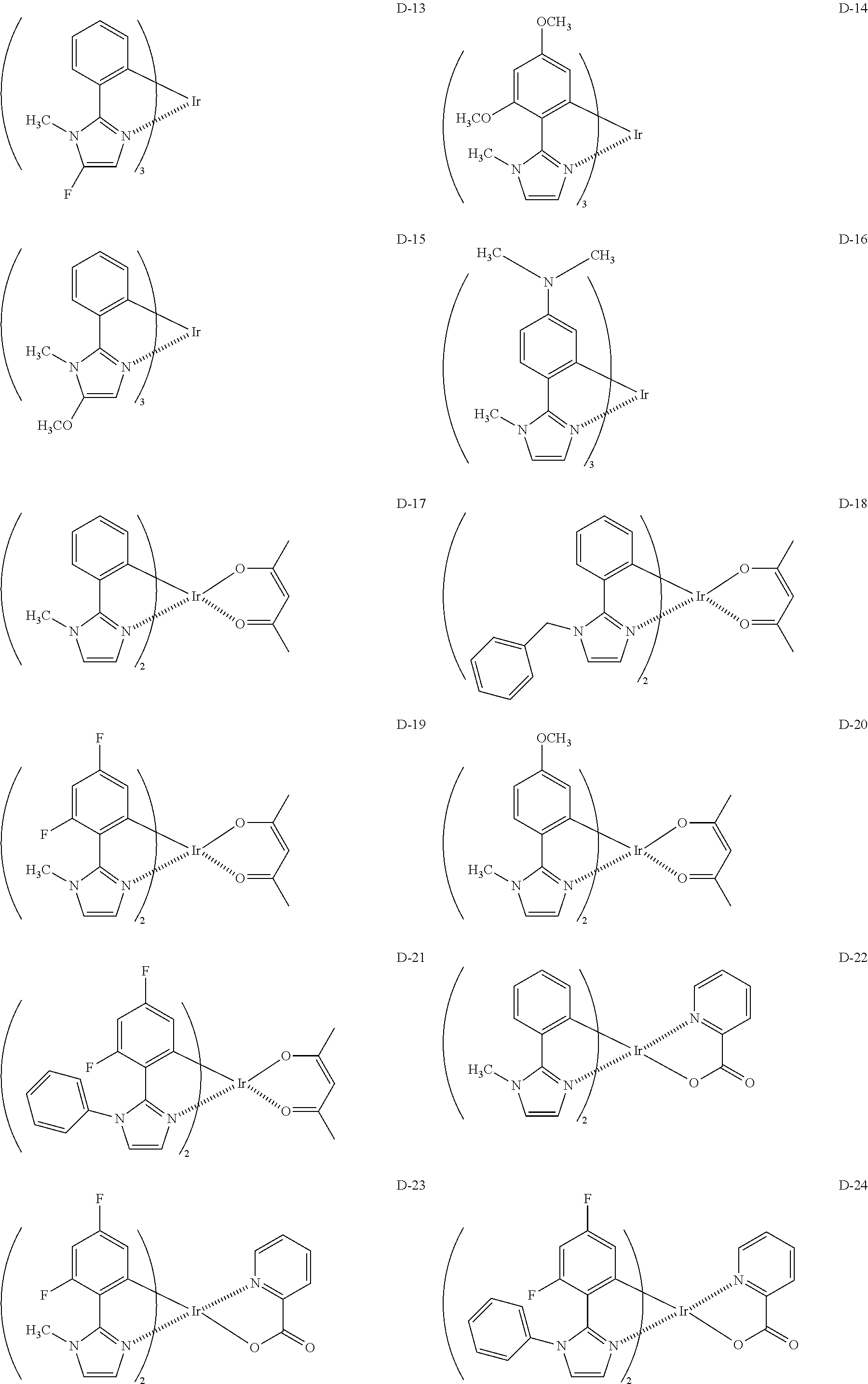

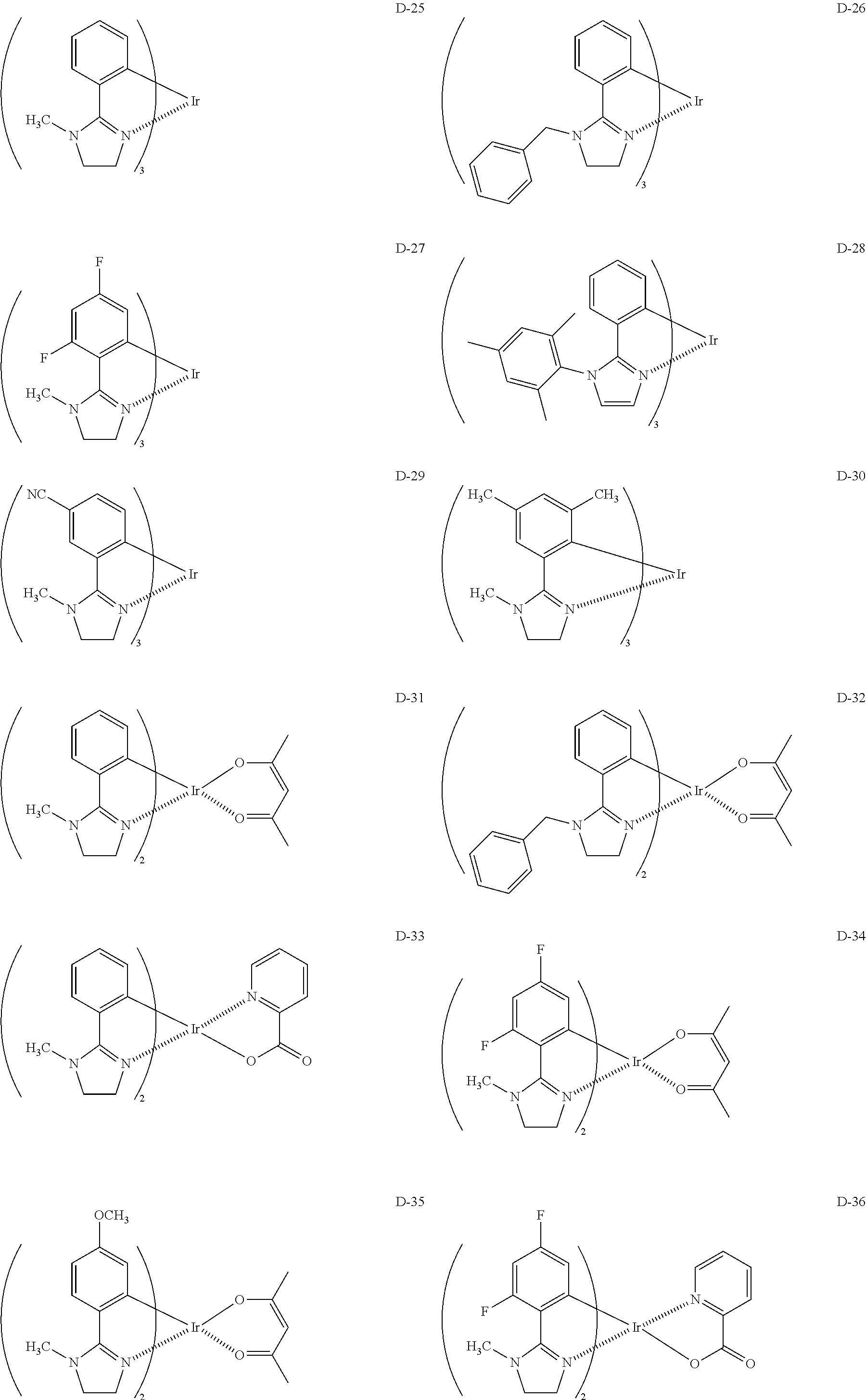

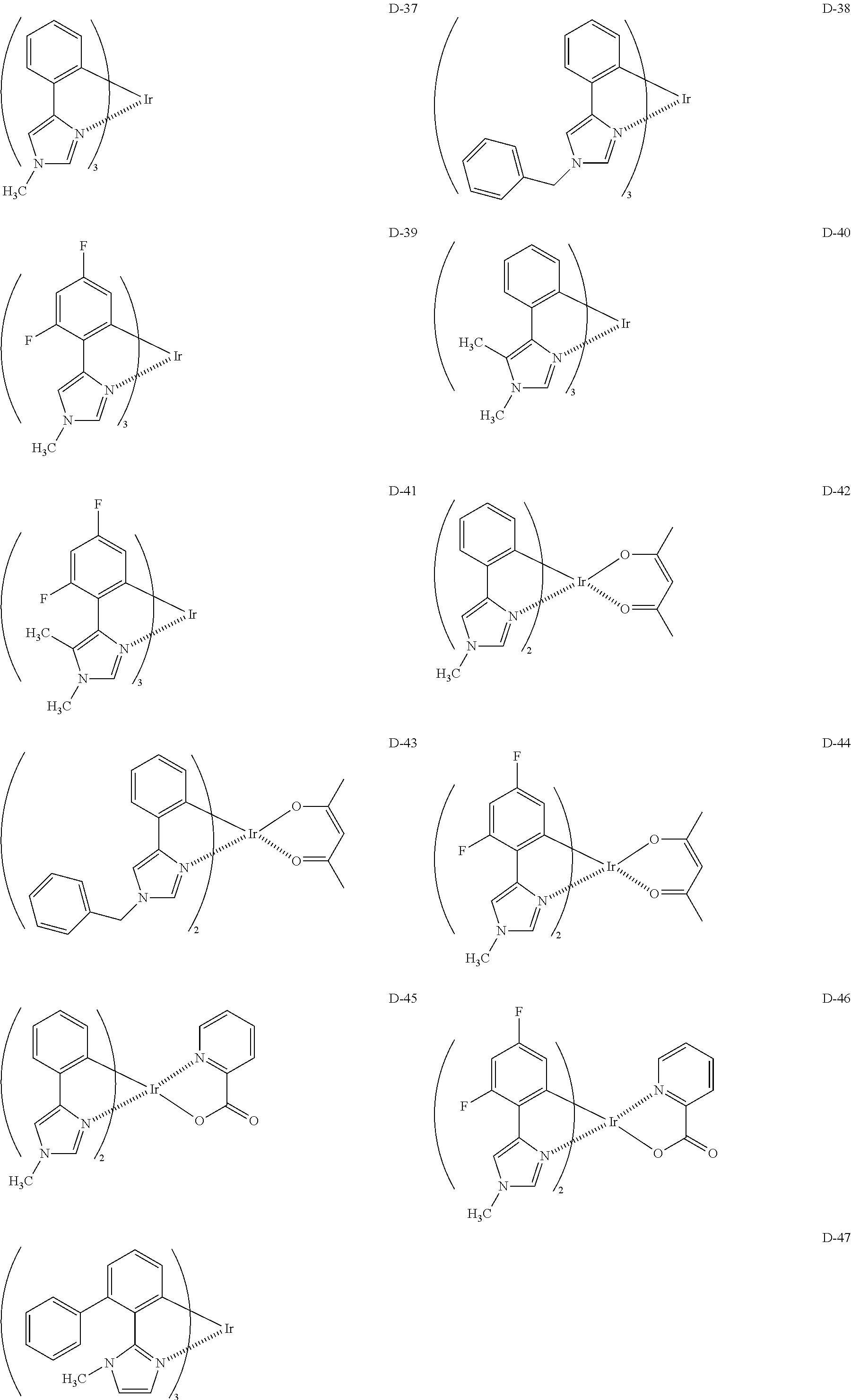

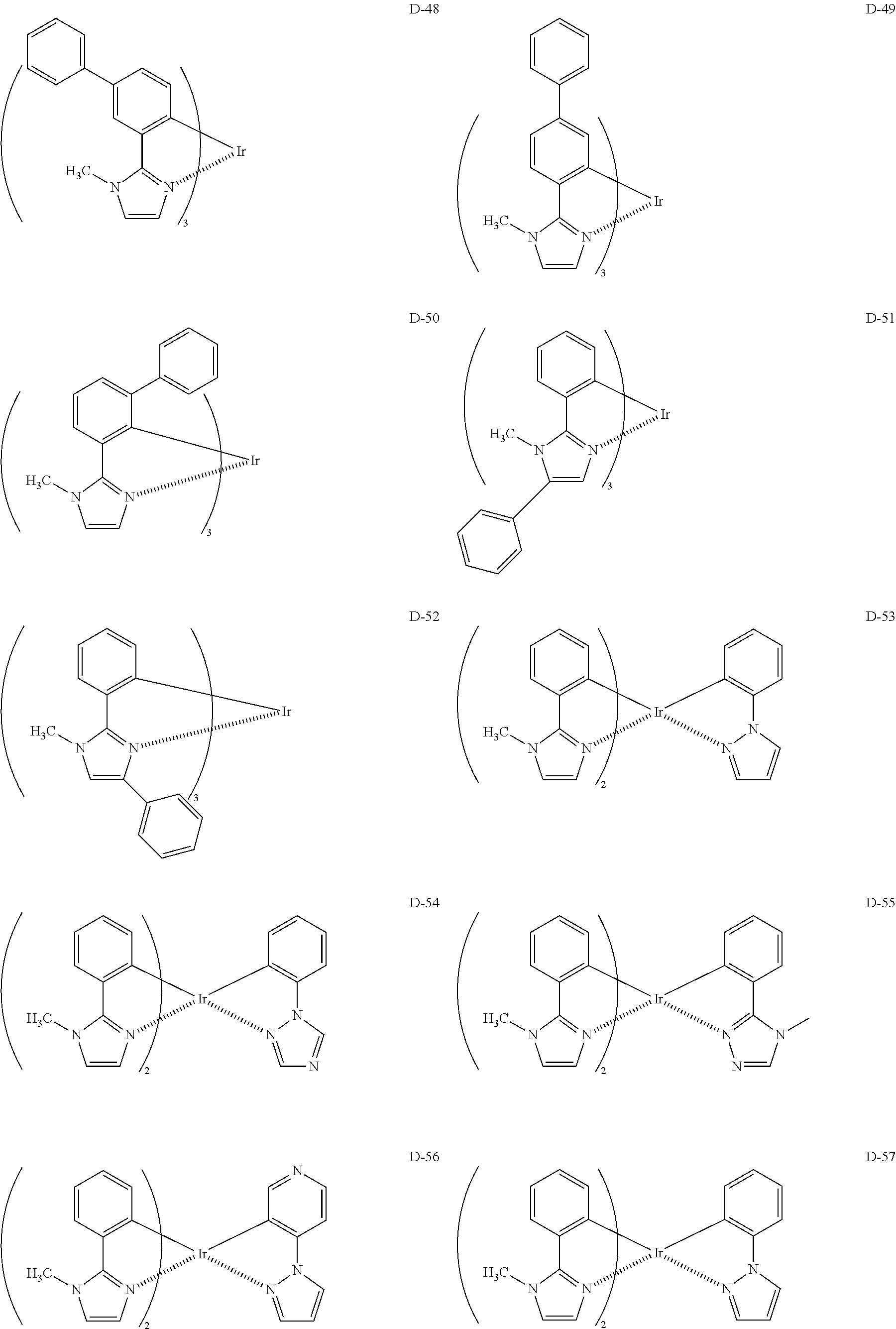

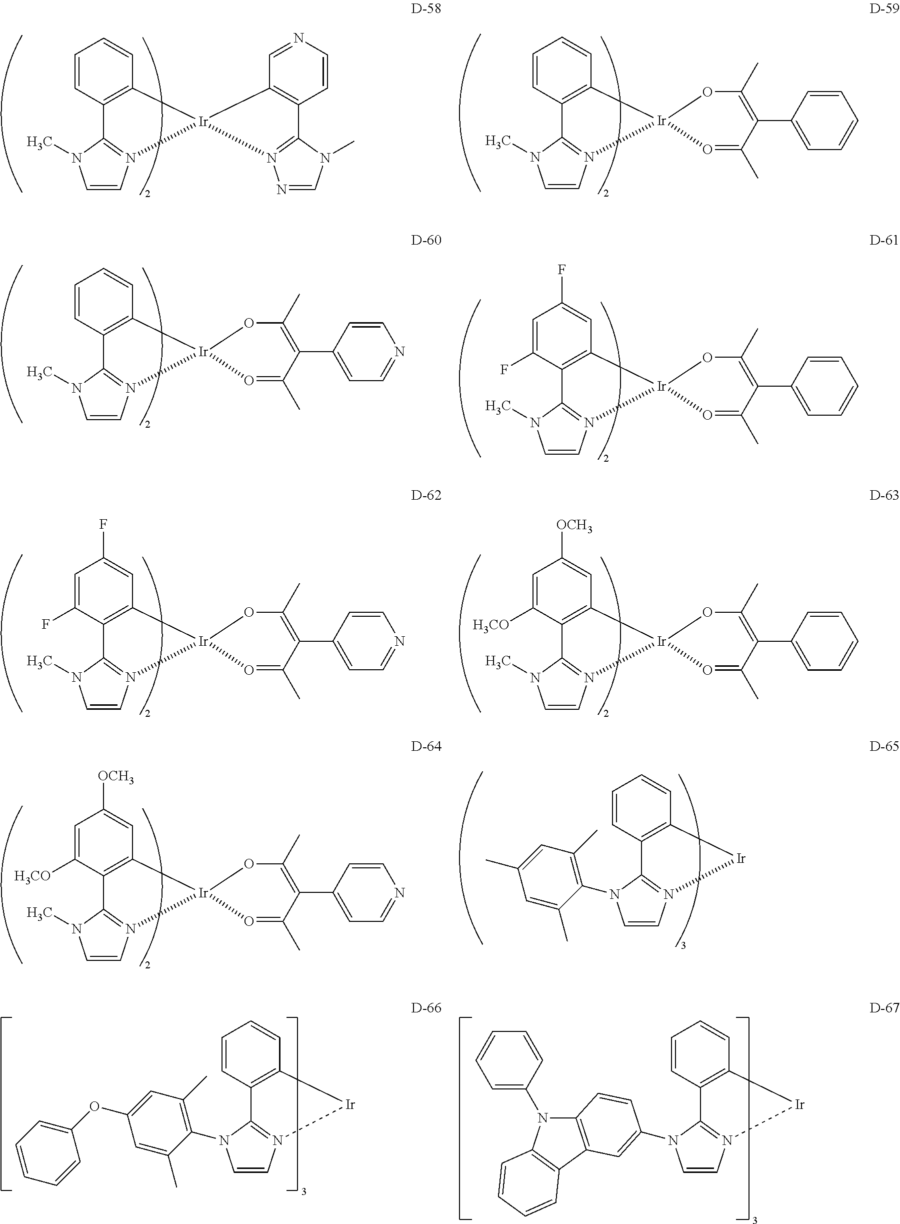

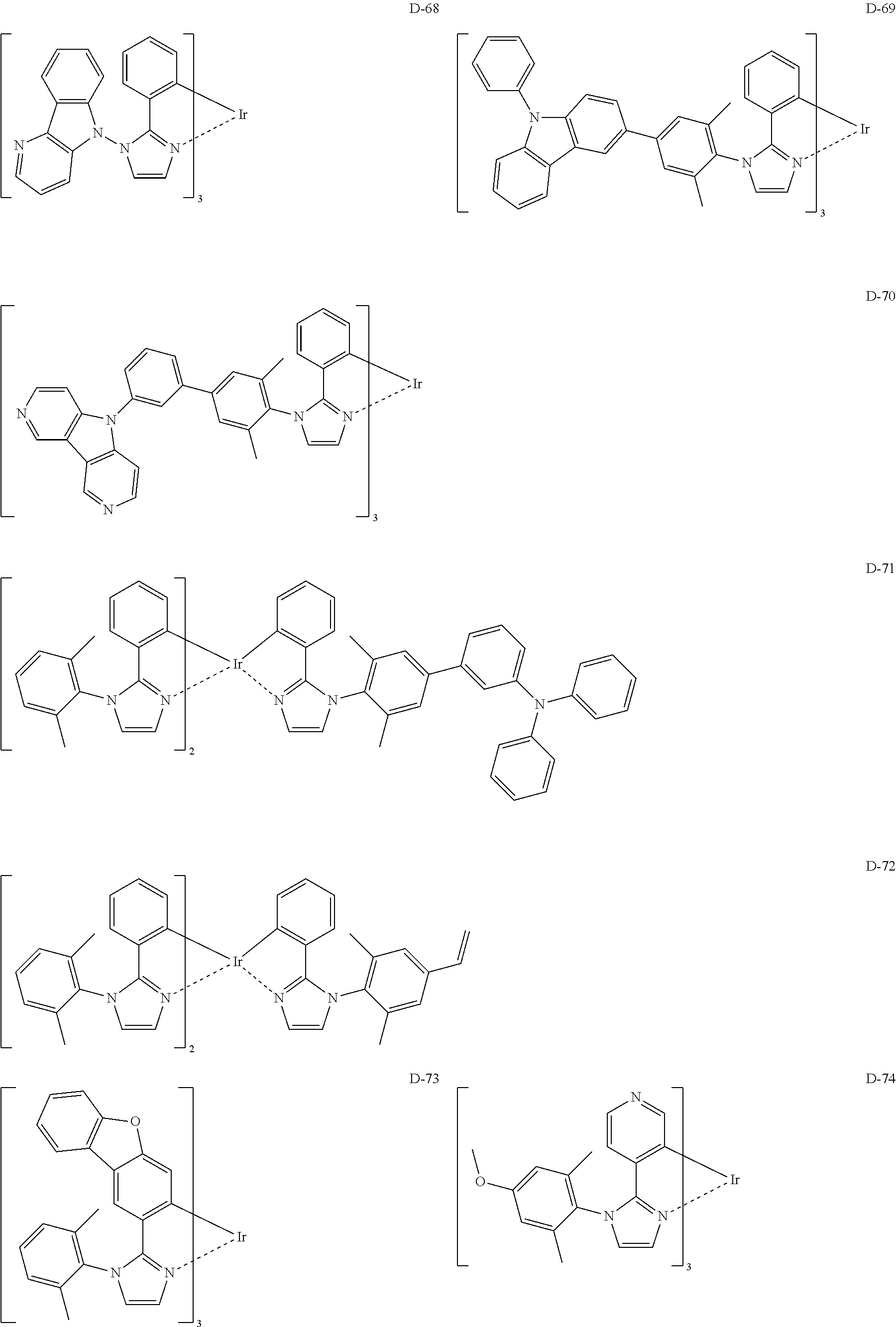

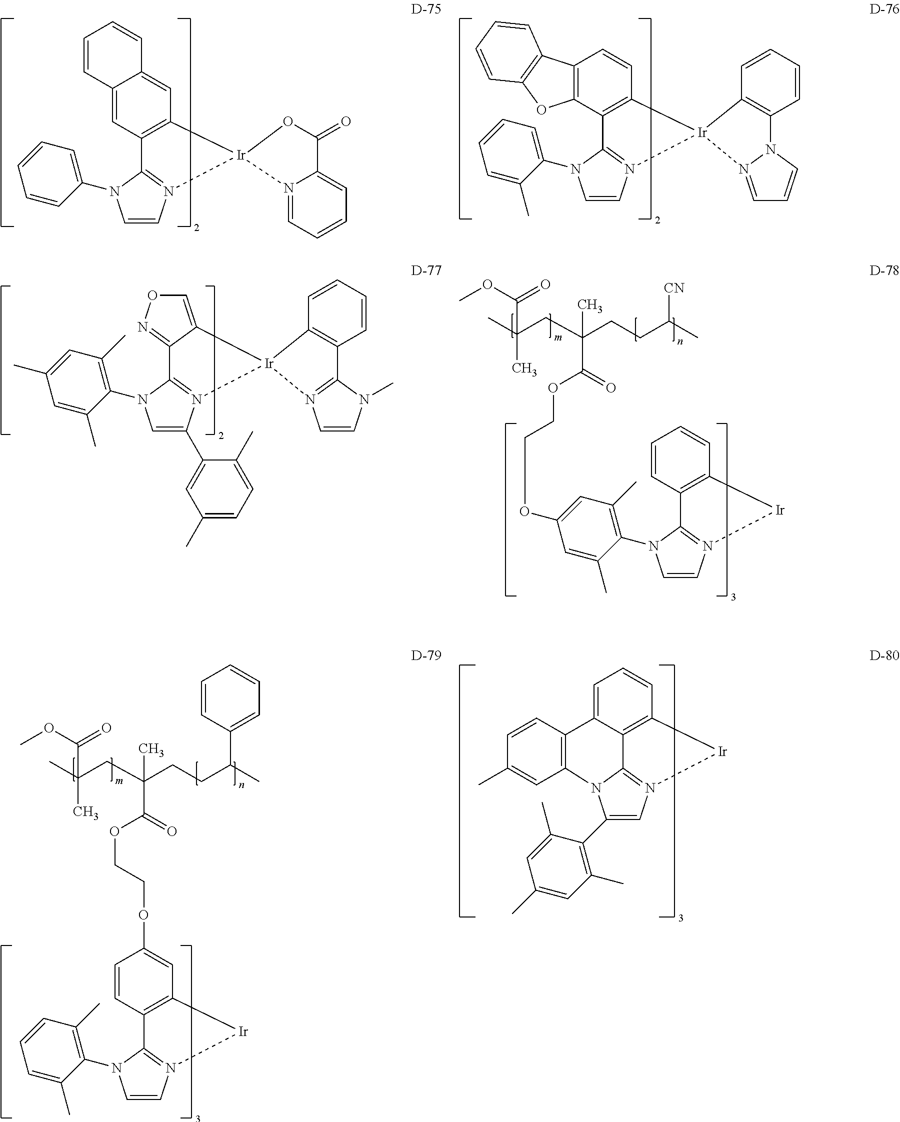

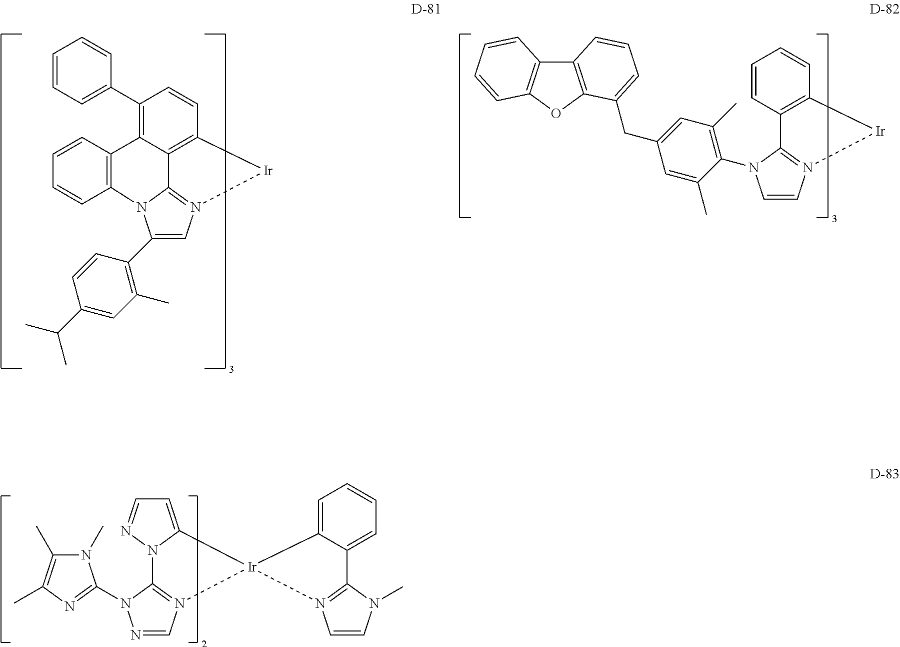

(3) Fluorescence Emitting Dopant

Examples of a fluorescence emitting dopant include a coumarin-based dye; a pyran-based dye; a cyanine-based dye; a croconium-based dye; a squarylium-based dye; an oxobenzanthracene-based dye; a fluorescein-based dye; a rhodamine-based dye; a pyrylium-based dye; a perylene-based dye; a stilbene-based dye; a polythiophene-based dye; and a rare-earth element complex-based phosphor.

<Injection Layers: Hole Injection Layer and Electron Injection Layer>

An injection layer may be provided as needed, and disposed between an anode or intermediate metal layer and a light emitting layer or hole transport layer, or between a cathode or intermediate metal layer and a light emitting layer or electron transport layer.

The injection layer refers to a layer disposed between organic layers or between an electrode and an intermediate metal layer. For example, its details have been described in Chapter 2, Section 2 “Electrode Materials” (page 123 to 166) of the “Organic EL Elements and Frontier of Their Industrial Use (published by NTS INC., Nov. 30, 1998). Examples of the injection layer include a hole injection layer (or anode buffer layer) and an electron injection layer (or cathode buffer layer).

The details of the hole injection layer (or anode buffer layer) have been described in JP-H09-45479A, JP-H09-260062A, JP-H08-288069A, etc. Specific examples include: a phthalocyanine buffer layer made of, for example, copper phthalocyanine; an oxide buffer layer made of, for example, vanadium oxide; an amorphous carbon buffer layer; and a polymer buffer layer using a conductive polymer such as polyaniline, emeraldine and/or polythiophene. Also, it is preferable to use materials disclosed in JP2003-519432.

A plurality of materials may be combined for the hole injection layer. In an embodiment of the present invention, however, it is preferable to use a single organic compound to deposit a film. The reasons include that a mixed ratio varies during production when a plurality of materials are mixed for usage. For example, there is an increased risk of performance variation due to a concentration difference within a film deposition layer on a substrate.

The thickness of the hole injection layer is usually, but not limited to, from about 0.1 to 100 nm and preferably from 1 to 30 nm.

Examples of a preferable material for an electron injection layer interposed between an electron transport layer and a cathode include alkali metals having a work function of 3 eV or less, alkali earth metals, and compounds containing the above metals. Specific examples of the alkali metal compound include potassium fluoride, lithium fluoride, sodium fluoride, cesium fluoride, lithium oxide, a lithium quinoline complex, and cesium carbonate. Preferred are lithium fluoride and cesium fluoride.

As a layer adjacent to an intermediate metal layer at the anode side, a layer containing an alkali metal compound or an alkali earth metal compound is unsuitable.

The thickness of the electron injection layer is usually, but not limited to, from about 0.1 to 10 nm and preferably from 0.1 to 2 nm.

<Block Layers: Hole Blocking Layer and Electron Blocking Layer>

A block layer may be provided as needed. For example, a hole blocking layer is illustrated in JP-H11-204258A, JP-H11-204359A, and page 237, etc., of the “Organic EL Elements and Frontier of Their Industrial Use (published by NTS INC., Nov. 30, 1998).

The hole blocking layer is made of a hole block material having a function of an electron transport layer in a broad sense and a markedly reduced ability to transport holes while having a function to transport electrons. Blocking holes while transporting electrons can increase the probability of recombination between holes and electrons. In addition, the below-described electron transport layer may be used as a hole blocking layer if necessary.

The hole blocking layer may be preferably disposed adjacent to a light-emitting layer.

Meanwhile, the electron blocking layer has a function of a hole transport layer in a broad sense. The electron blocking layer is made of a material having a function to transport holes and a markedly reduced ability to transport electrons. Blocking electrons while transporting holes can increase the probability of recombination between holes and electrons. In addition, the below-described hole transport layer may be used as an electron blocking layer if necessary.

A hole blocking layer and an electron blocking layer of the present invention have a thickness of preferably from 3 to 100 nm and more preferably from 5 to 30 nm.

<Hole Transport Layer>

A hole transport layer is made of a hole transport material having a function to transport holes. In a broad sense, the hole transport layer includes a hole injection layer and/or an electron blocking layer.

A monolayer or a plurality of layers of the hole transport layer may be provided.

The hole transport material has characteristics of hole injection or transport or electron barrier functions. The material may be organic matter or inorganic matter. Examples of the material include triazole derivatives, oxadiazole derivatives, imidazole derivatives, polyarylalkane derivatives, pyrazoline derivatives and pyrazolone derivatives, phenylenediamine derivatives, arylamine derivatives, amino-substituted chalcone derivatives, oxazole derivatives, styryl anthracene derivatives, fluorenone derivatives, hydrazone derivatives, stilbene derivatives, silazane derivatives, aniline-based copolymers, conductive polymer oligomers, and thiophene oligomers, in particular.

The above compounds can be used as the hole transport material. However, more preferred are porphyrin compounds, aromatic tertiary amine compounds, and styrylamine compounds. Most preferred are aromatic tertiary amine compounds.

Representative examples of the aromatic tertiary amine compounds and the styrylamine compounds include N,N,N′,N′-tetraphenyl-4,4′-diaminophenyl; N,N′-diphenyl-N,N′-bis(3-methylphenyl)-[1,1′-biphenyl]-4,4-diamine (TPD); 2,2-bis(4-di-p-tolylaminophenyl)propane; 1,1-bis(4-di-p-tolylaminophenyl)cyclohexane; N,N,N′,N′-tetra-p-tolyl-4,4′-diaminobiphenyl; 1,1-bis(4-di-p-tolylaminophenyl)-4-phenylcyclohexane; bis(4-dimethylamino-2-methylphenyl)phenylmethane; bis(4-di-p-tolylaminophenyl)phenylmethane; N,N′-diphenyl-N,N-di(4-methoxyphenyl)-4,4′-diaminobiphenyl; N,N,N′,N′-tetraphenyl-4,4′-diaminodiphenylether; 4,4′-bis(diphenylamino)quaternary phenyl; N,N,N-tri(p-tolyl)amine; 4-(di-p-tolylamino)-4′-[4-(di-p-tolylamino)styryl]stilbene; 4-N,N-diphenylamino-(2-diphenylvinyl)benzene; 3-methoxy-4′-N,N-diphenylaminostilbenzene; and N-phenylcarbazole. Additional examples include: a compound having two condensed aromatic rings per molecule as disclosed in the specification of U.S. Pat. No. 5,061,569B, such as 4,4′-bis[N-(1-naphthyl)-N-phenylamino]biphenyl (NPD); and a compound having three Star Burst-type triphenylamine units as disclosed in JP-H04-308688 A, such as 4,4′,4″-tris[N-(3-methylphenyl)-N-phenylamino]triphenylamine (MTDATA).

Further examples that can be used include polymer materials in which the above materials have been introduced into a polymer chain or in which the above materials are used as a main chain of a polymer. Furthermore, p-type Si and p-type SiC inorganic compounds, for example, can be used as the hole injection material and/or the hole transport material.

Moreover, it is possible to use a hole transport material having what is called p-type semiconductor characteristics as disclosed in JP-H04-297076 A, JP2000-196140 A, JP2001-102175 A, J. Appl. Phys., 95, 5773 (2004), JP-H11-251067 A, an article by J. Huang et. al. (Applied Physics Letters 80(2002), p. 139), and JP2003-519432 A. In an embodiment of the present invention, these materials are preferably used because a light-emitting element having a higher efficiency can be produced.

One or two or more kinds of the above materials may be used to form a monolayer structure of the hole transport layer.

The thickness of the hole transport layer is usually, but not limited to, from about 5 nm to 5 μm and preferably from 5 to 200 nm.

<Electron Transport Layer>

An electron transport layer is made of a material having a function to transport electrons.

A monolayer or a plurality of layers of the electron transport layer may be provided.

Electron transport materials used for the electron transport layer may have a function to transfer into a light-emitting layer electrons injected through a cathode or an intermediate metal layer. Any of the materials may be selected from conventionally known compounds. Examples of the materials include: nitro-substituted fluorene derivatives; diphenylquinone derivatives; thiopyrandioxide derivatives; bipyridyl derivatives; fluorenylidene methane derivative; carbodiimide, anthraquinodimethane, and anthrone derivatives; and oxadiazole derivatives. Additional examples of the electron transport materials that can be used include: a thiadiazole derivative in which an oxygen atom of an oxadiazole ring is substituted with a sulfur atom in the above oxadiazole derivatives; and a quinoxaline derivative having a quinoxaline ring known as an electron-withdrawing substituent. Further examples that can be used include polymer materials in which the above materials have been introduced into a polymer chain or in which the above materials are used as a main chain of a polymer.

In an embodiment of the present invention, when an electron transport layer is disposed adjacent to an intermediate metal layer, preferred is a compound including a pyridine ring in its structure.

Furthermore, examples of the electron transport materials that can be used include 8-quinolinol-derivative-containing metal complexes such as tris(8-quinolinol)aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum, and bis(8-quinolinol)zinc (Znq), and metal complexes in which a center metal of these metal complexes is replaced with In, Mg, Cu, Ca, Sn, Ga, or Pb. Other electron transport materials that can be preferably used include metal-free or metal phthalocyanine and the above phthalocyanine whose terminal is substituted with an alkyl group or a sulfo group. Moreover, a distyrylpyrazine derivative that can also be used as a light-emitting layer material may be used as the electron transport material. In substantially the same manner as in the hole injection layer and the hole transport layer, n-type Si or n-type SiC inorganic semiconductors, for example, may also be used as the electron transport material.

A plurality of materials may be combined for the electron transport layer. The layer may be doped with an alkali metal, an alkali earth metal, an alkali metal compound, or an alkali earth metal compound. However, a single organic compound is preferably used to deposit a film for the formation of an electron transport layer of the present invention. The reasons include that a mixed ratio varies during production when a plurality of materials are mixed for usage. For example, there is an increased risk of performance variation due to a concentration difference within a film deposition layer on a substrate.

In an embodiment of the present invention, use of an intermediate metal layer containing a metal with a low work function makes it possible to achieve preferable performance without damaging injection of electrons from the intermediate metal layer even if an alkali metal, for example, is not doped.

The glass transition temperature of an organic compound included in the electron transport layer is preferably 110° C. or higher in view of excellent high-temperature storage and high-temperature process stability.

The thickness of the electron transport layer is usually, but not limited to, from about 5 nm to 5 μm and preferably from 5 to 200 nm.

<Supporting Substrate (2)>

Any kind of glass or plastic may be used for a supporting substrate that is used for an organic EL element of the present invention. The supporting substrate may be transparent or non-transparent. When light is extracted from the supporting substrate side, the supporting substrate is preferably transparent. Examples of a preferable transparent supporting substrate include a glass piece, a quartz piece, and a transparent resin film. As the supporting substrate, more preferred is a resin film capable of imparting flexibility to an organic EL element.

Examples of the resin film include: polyester such as polyethylene terephthalate (PET) and polyethylene naphthalate (PEN); polyethylene; polypropylene; cellophane; cellulose esters or derivatives thereof such as cellulose diacetate, cellulose triacetate (TAC), cellulose acetate butylate, cellulose acetate propionate (CAP), cellulose acetate phthalate, and cellulose nitrate; polyvinylidene chloride; polyvinyl alcohol; polyethylene vinyl alcohol; syndiotactic polystyrene; polycarbonate; norbornene resins; polymethyl pentene; polyether ketone; polyimide; polyether sulfone (PES); polyphenylene sulfide; polysulfone derivatives; polyether imide; polyether ketone imide; polyamide; fluorine resins; nylon; polymethyl methacrylate; acryl or polyarylate derivatives; and cycloolefin-based resins such as ARTON (the product name; produced by JSR Inc.) or APEL (the product name; produced by Mitsui Chemicals Inc.).

The surface of the resin film may be coated with a film containing inorganic matter or organic matter or coated with a hybrid film containing both. It is preferable to use a gas barrier film having a water vapor permeability of 0.01 g/(m²·24 h) or less as measured using a method according to JIS K 7129-1992. It is more preferable to use an enhanced gas barrier film having an oxygen permeability of 1×10⁻³ ml/(m²·24 h·atm) or less and an water vapor permeability of 1×10⁻³ g/(m²·24 h) or less as measured using a method according to JIS K 7126-1992. It is still more preferable to use a gas barrier film having an oxygen permeability of 1×10⁻⁵ ml/(m²·24 h·atm) or less and a water vapor permeability of 1×10⁻⁵ g/(m²·24 h).

A material used to form a gas barrier film may be a material having a function to prevent infiltration of moisture and/or oxygen that may deteriorate a device. Examples of the material that can be used include silicon oxide, silicon dioxide, and silicon nitride. In order to improve weakness of the gas barrier film, it is more preferable to provide a lamination structure including a layer containing these inorganic materials and a layer containing organic materials. The order of layers in the lamination containing the inorganic layer and the organic layer is not particularly limited. Preferably, the above layers, however, are alternately stacked multiple times.

Examples of a method for forming a gas barrier film include: but are not particularly limited to, a vacuum evaporation method, sputtering, reactive sputtering, a molecular beam epitaxy method, a cluster ion-beam method, ion plating, plasma polymerization, atmospheric plasma polymerization, plasma CVD, laser CVD, thermal CVD, and a coating method. Also, atmospheric plasma polymerization disclosed in JP2004-68143 A can be suitably used.

Examples of the non-transparent supporting substrate include metal plates or films made of aluminum or stainless, non-transparent resin substrates, and substrates made of ceramics.

<Sealing>

Examples of sealing means used to seal an organic EL element of the present invention can include a method for attaching a sealing member to an electrode and/or a supporting substrate by using an adhesive.

The sealing member may be disposed so as to cover a display area of an organic EL element, and may be concave or flat.

In addition, the transparency and electrical insulation of the sealing member are not particularly limited.

Specific examples include a glass plate, a polymer plate and film, and a metal plate and film. Examples of the glass plate include, in particular, a soda lime glass plate, a barium.strontium-containing glass plate, a lead glass plate, an aluminosilicate glass plate, a borosilicate glass plate, a barium borosilicate glass plate, and a quartz plate. In addition, examples of the polymer plate include a polycarbonate plate, an acryl plate, a polyethylene terephthalate plate, a polyether sulfide plate, and a polysulfone plate. Examples of the metal plate include plates made of at least one metal or alloy thereof selected form the group consisting of stainless, iron, copper, aluminum, magnesium, nickel, zinc, chromium, titanium, molybdenum, silicon, germanium, and tantalum.

In an embodiment of the present invention, a polymer film or a metal film may be preferably used because their use makes a film of an organic EL element thinner. Further, it is preferable to use a polymer film having an oxygen permeability of 1×10⁻³ ml/(m²·24 h·atm) or less and a water vapor permeability of 1×10⁻³ g/(m²·24 h) or less. Furthermore, it is more preferable to use a polymer film having an oxygen permeability of 1×10⁻⁵ ml/(m²·24 h·atm) or less and a water vapor permeability of 1×10⁻⁵ g/(m²·24 h).

Sandblasting or chemical etching may be used for a method for processing a concave sealing member. In case of a metal plate, bending process via pressing or bending may be used for the method.

Specific examples of the adhesive include: photocurable and thermal curing adhesives containing an acrylate-based oligomer and/or a methacrylate-based oligomer having a reactive vinyl group; and moisture-setting adhesives containing a 2-cyano acrylate ester. Additional examples can include epoxy-based thermal curing and chemical setting (two kinds of liquid are mixed) adhesives. Further examples can include hot melt polyamide, polyester, and polyolefin. Furthermore, the examples can include cation-setting UV-curable epoxy resin adhesives.

Note that the organic EL element may be deteriorated due to heat treatment. Accordingly, it is preferable to use an adhesive capable of being bonded and cured at from room temperature (25° C.) to 80° C. In addition, a desiccant may be dispersed in the adhesive. When the adhesive is used for a sealing portion, a commercially available dispenser may be used or screen printing may be employed for printing.

It is preferable to inject a material into an space between the sealing member and a display area of the organic EL element, the gas phase and liquid phase material including an inert gas such as nitrogen and argon and an inert fluid such as hydrocarbon fluoride and silicone oil. Also, the space may be vacuumed. In addition, a hygroscopic compound may be charged in the inside of the space.

Examples of the hygroscopic compound include metal oxides (e.g., sodium oxide, potassium oxide, calcium oxide, barium oxide, magnesium oxide, aluminum oxide); sulfates (e.g., sodium sulfate, calcium sulfate, magnesium sulfate, cobalt sulfate); metal halogenated compounds (e.g., calcium chloride, magnesium chloride, cesium fluoride, tantalum fluoride, cerium bromide, magnesium bromide, barium iodide, magnesium iodide); and perchlorates (e.g., barium perchlorate, magnesium perchlorate). An anhydrous salt is preferably used for the sulfates, metal halogenated compounds, and perchlorates.

<Protection Film and Protection Plate>

In order to increase the mechanical strength of the organic EL element, a protection film or a protection plate may be provided outside the above sealing film. When the sealing film is used for sealing, in particular, its mechanical strength is not necessarily high. Accordingly, it is preferable to provide such a protection film and/or a protection plate. The same materials can be used as the material that can be used for the above protection film and plate, and examples include a glass plate, a polymer plate and film, and a metal plate and film. In view of making a film thinner and weigh less, it is preferable to use a polymer film.

<Anode (4)>

For an anode, a metal, alloy, or electrically conductive compound having an increased work function (4 eV or higher) and a mixture thereof are preferably used as an electrode material. Specific examples of such an electrode material include conductive transparent materials containing a metal such as Au, Ag, or Al, CuI, indium-tin oxide (ITO), SnO₂, and/or ZnO. Additional examples that can be used include materials capable of producing an amorphous transparent conductive film made of, for example, IDIXO (In₂O₃—ZnO).

With regard to the anode, these electrode materials may be used to form a thin film according to a method such as vapor deposition and/or sputtering. Also, a pattern with a desired shape may be formed using photolithography. Alternatively, when a pattern precision is not required so much (e.g., an accuracy of 100 μm or more), a mask with a desired shape is used to perform patterning at the time of vapor deposition and/or to perform sputtering using the above electrode materials. Also, when an applicable substance such as an organic conductive compound is used, a wet film formation method such as printing and/or coating may be used.

When light is extracted from the anode side, it is preferable to have a transmittance of more than 10%.

In addition, the anode preferably has a sheet resistance value of several hundreds Ω/□ or less.

Depending on the material, the film thickness is selected within a range usually from 5 to 1000 nm and preferably from 5 to 200 nm.

<Cathode (12)>

Meanwhile, for a cathode, a metal, alloy, or electrically conductive compound and a mixture thereof are preferably used as an electrode material. Specific examples of such an electrode material include sodium, a sodium-potassium alloy, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, a rare-earth metal, silver, aluminum, and the like. Among them, in view of electron injection and durability against oxidation, preferred is a mixture containing an electron injectable metal and a group 2 metal that is a stable metal having a larger work function value than the former metal. Preferable examples include a magnesium/silver mixture, a magnesium/aluminum mixture, a magnesium/indium mixture, an aluminum/aluminum oxide (Al₂O₃) mixture, a lithium/aluminum mixture, aluminum, silver, and the like.

With regard to the cathode, these electrode materials may be used to form a thin film according to a method such as vapor deposition and/or sputtering for its production.

In addition, the cathode preferably has a sheet resistance value of several hundreds Ω/□ or less. The film thickness is selected within a range usually from 5 nm to 5 μm and preferably from 5 to 200 nm.

Note that in order to make emitted light pass through the element, one of the anode and the cathode of the organic EL element may be transparent or semi-transparent. This increases emission brightness and is thus suitable.

In addition, the above material is used to prepare a cathode at a film thickness of from 1 to 20 nm. Next, on the cathode is disposed a conductive transparent material as indicated in the description of the anode. Then, a transparent or semi-transparent cathode can be prepared. Such an application makes it possible to produce an element in which both the anode and the cathode are transparent.

The following further details construction of a characteristic organic EL element of the present invention.

<<Patterned Layers in Light Emitting Unit>>

An organic EL element of the present invention includes N (N is an integer of 2 or more) light emitting units. These N light emitting units each have one or more organic functional layers including the above-described light-emitting layer. Meanwhile, at least one organic functional layer constituting each light emitting unit is subjected to individual or simultaneous patterning using the below-described procedure.

In addition, each light emitting unit of an organic EL element of the present invention emits light with different light-emitting patterns. As used herein, the phrase “emits light with different light-emitting patterns” means the following cases. In one case, light is emitted so as to display the shapes of different drawings (designs and/or patterns), letters, and images on an organic EL element. In another case, light is emitted so as to display different positions and/or directions of a drawing. In another case, light is emitted so as to display different hue, chroma, and/or value.

Then, in an organic EL element of the present invention, patterning of each light emitting unit includes the following cases. That is, the shapes of the patterning may be identical or not identical in a stacking direction. Accordingly, hereinafter, the cases are separately described.

<Organic EL Element Having Identical Patterning Shape>

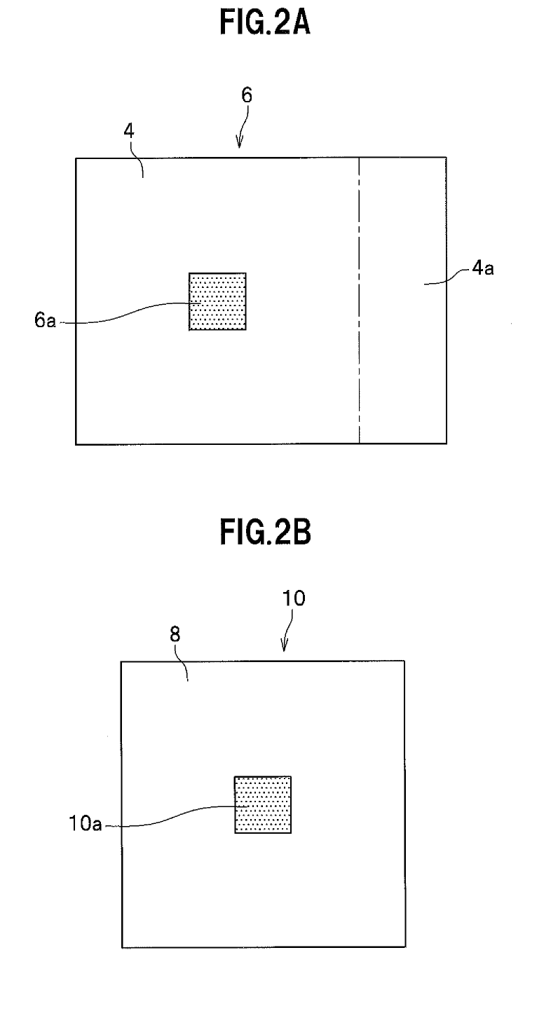

First, FIGS. 1 and 2 are used to describe an embodiment of an organic EL element in which the patterning shapes of different light emitting units are identical in a stacking direction.

Note that the following illustrates a case where the organic EL element 1 shown in FIG. 1 includes an anode (first electrode) 4 and a supporting substrate 2 made of highly transparent materials. Also, a cathode (second electrode) 12 is made of aluminum with low transparency. That is, in this case, the anode 4 is an “electrode at the light-emitting surface side”. The light emitting unit 6 is the “first light emitting unit disposed closest to the electrode at the light-emitting surface side”.

As illustrated in FIG. 2A, an organic functional layer 6a of the first light emitting unit 6 stacked on the anode 4 is subjected to patterning to have a square shape. Next, as illustrated in FIG. 2B, an organic functional layer 10a of the second light emitting unit 10 stacked on an intermediate metal layer 8 is subjected to patterning to have a square shape. The shape is identical to the shape of the patterning of the organic functional layer 6a in a stacking direction.

Here, the organic functional layers 6a and 10a as illustrated in FIG. 2 may each be (1) a layer subjected to patterning using a mask during formation of the organic functional layer, (2) a layer subjected to patterning using light irradiation after formation of the organic functional layer, or (3) a layer subjected to patterning using a mask during formation of the organic functional layer and subjected to patterning using light irradiation after the formation of the organic functional layer.

That is, when the light emitting units 6 and 10 of the organic EL element of the present invention each have an identical patterning shape in a stacking direction, at least one of the organic functional layers 6a and 10a constituting the light emitting units 6 and 10, respectively, may be any of the above layers (1) to (3).

Note that the above layer (2) is a layer subjected to patterning using light irradiation on a non-light-emitting area so as to modify the function of the organic functional layer (i.e., the light-emitting function is lost).

Because of this, the non-light-emitting area somewhat consumes electric power. By contrast, in the above layer (1) or (3), an organic functional layer is not formed on the non-light-emitting area in the first place. Accordingly, electric power is consumed at only the light-emitting portion.

Hence, based on the viewpoint of reduced power consumption, the organic functional layers 6a and 10a are preferably the above layer (1) or (3).

Meanwhile, when an organic functional layer is formed by vapor deposition, for example, the above layer (1) contains a fuzzy film portion after the vapor deposition. Consequently, an area surrounding the square may have some emission brightness and the light-emitting pattern may thus be emission pattern hazy. By contrast, the above layer (3) is subjected to patterning using a mask during formation of an organic functional layer and a portion of the organic functional layer as produced outside the mask is trimmed using light irradiation. Consequently, a very clear light-emitting pattern can be obtained.

Hence, from the viewpoint of shape clarity of the light-emitting pattern, the organic functional layers 6a and 10a are preferably the above layer (3).

In this regard, however, the above layer (1) can be produced without a light irradiation process. Hence, based on the viewpoint of productive efficiency, the organic functional layers 6a and 10a are preferably the above layer (1).

Next, the organic EL element 1 of the present invention includes a first light emitting unit 6 containing the organic functional layer 6a and a second light emitting unit 10 containing the organic functional layer 10a. The respective light emitting units emit different colors such as white and red.

According to this configuration, when only the first light emitting unit 6 is operated, a square and white light-emitting pattern is displayed. When only the second light emitting unit 10 is operated, a square and red light-emitting pattern is displayed.

<Organic EL Element Having Different Patterning Shapes>

Next, FIGS. 1, 4, and 6 are used to describe embodiments of an organic EL element in which the patterning shapes of different light emitting units are not identical in a stacking direction.

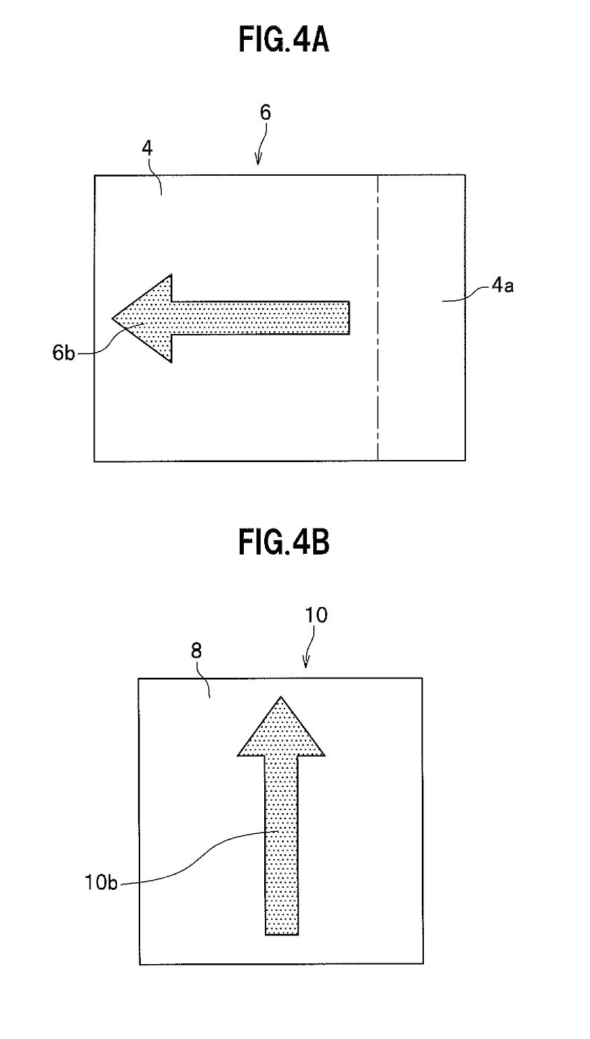

As illustrated in FIG. 4A, an organic functional layer 6b of the first light emitting unit 6 stacked on the anode 4 is subjected to patterning to have a left-oriented arrow. As illustrated in FIG. 4B, an organic functional layer 10b of the second light emitting unit 10 stacked on the intermediate metal layer 8 is subjected to patterning to have an up-oriented arrow. That is, the patterning shapes of the organic functional layers 6b and 10b are not identical in a stacking direction.

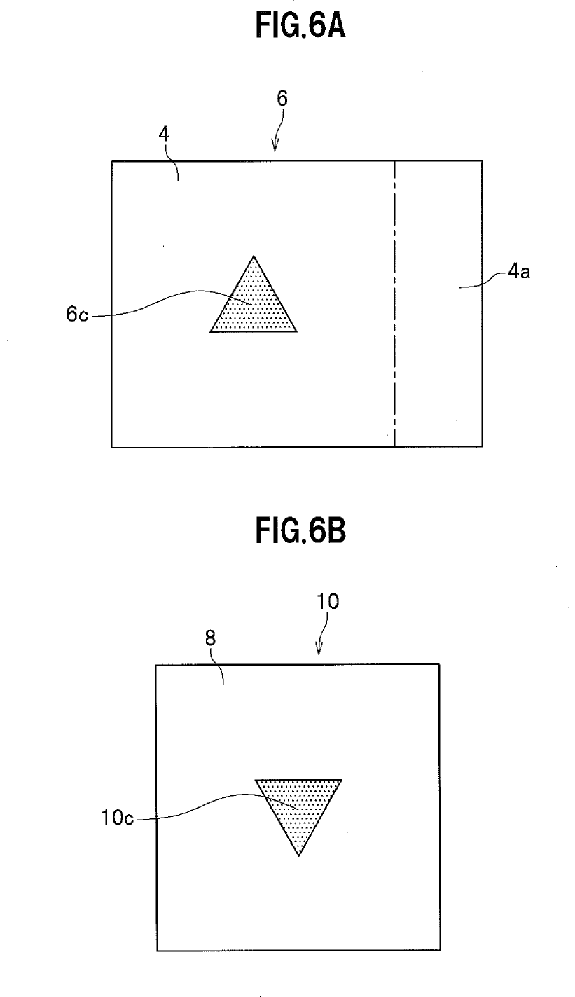

In addition, as illustrated in FIG. 6A, an organic functional layer 6c of the first light emitting unit 6 stacked on the anode 4 is subjected to patterning to have an up-oriented triangle. As illustrated in FIG. 6B, an organic functional layer 10c of the second light emitting unit 10 stacked on the intermediate metal layer 8 is subjected to patterning to have a down-oriented triangle. That is, the patterning shapes of the organic functional layers 6c and 10c are not identical in a stacking direction.

Here, the organic functional layers 6b as illustrated in FIG. 4A and the organic functional layers 6c as illustrated in FIG. 6A may each be (1) a layer subjected to patterning using a mask during formation of the organic functional layer, (2) a layer subjected to patterning using light irradiation after formation of the organic functional layer, or (3) a layer subjected to patterning using a mask during formation of the organic functional layer and subjected to patterning using light irradiation after the formation of the organic functional layer.

That is, when the light emitting units 6 and 10 of the organic EL element 1 of the present invention have different patterning shapes in a stacking direction, at least one organic functional layer 6b or 6c constituting the first light emitting unit 6 may be any of the above layers (1) to (3).

By contrast, the organic functional layers 10b as illustrated in FIG. 4B and the organic functional layers 10c as illustrated in FIG. 6B may each be (1) a layer subjected to patterning using a mask during formation of the organic functional layer or (3) a layer subjected to patterning using a mask during formation of the organic functional layer and subjected to patterning using light irradiation after the formation of the organic functional layer.

That is, when the light emitting units 6 and 10 of the organic EL element 1 of the present invention have different patterning shapes in a stacking direction, at least one organic functional layer 10b or 10c constituting the second light emitting unit 10 (i.e., a light emitting unit other than the first light emitting unit 6) may be the above layer (1) or (3).

Note that at the light-emitting surface side of the second light emitting unit 10 of the organic EL element 1 of the present invention (i.e., at the side of light irradiation during a light irradiation process), not only the supporting substrate 2 and the anode 4 but also the first light emitting unit 6 are provided. Accordingly, when the second light emitting unit 10 is subjected to patterning using only light irradiation, the first light emitting unit 6 is also subjected to the patterning.

Hence, it is not preferable to set the organic functional layer 10b as illustrated in FIG. 4B and the organic functional layer 10c as illustrated in FIG. 6B as the above layer (2) because part of the light-emitting pattern of the first light emitting unit 6 is going to be modified.

Note that in substantially the same manner as in the “organic EL element having an identical patterning shape”, the organic functional layers 6b, 10b, 6c, and 10c are preferably either the above layer (1) or (3) in view of reduced power consumption. In addition, based on the viewpoint of clear light-emitting pattern shape, the organic functional layers 6b, 10b, 6c, and 10c are preferably the above layer (3). In this regard, however, based on the viewpoint of productive efficiency, the organic functional layers 6b, 10b, 6c, and 10c are preferably the above layer (1).

According to the embodiment illustrated in FIG. 4, when only the first light emitting unit 6 is operated, a light-emitting pattern with a left-oriented arrow is displayed. When only the second light emitting unit 10 is operated, a light-emitting pattern with an up-oriented arrow is displayed.

In addition, according to the embodiment illustrated in FIG. 6, when only the first light emitting unit 6 is operated, a light-emitting pattern with an up-oriented triangle is displayed. When only the second light emitting unit 10 is operated, a light-emitting pattern with a down-oriented triangle is displayed. Further, when the first light emitting unit 6 and the second light emitting unit 10 are simultaneously operated, what is called a hexagram light-emitting pattern, which has therein superimposed triangles shown in FIGS. 6A and 6B, is displayed.

Note that in the embodiments as illustrated in FIGS. 4 and 6, the first light emitting unit 6 and the second light emitting unit 10 each have any kind of emission color. The color may be the same or different.

Hereinabove, FIGS. 1 and 2 are used to illustrate the case where only the color of the light-emitting pattern is different in each light emitting unit. FIGS. 1, 4, and 6 are used to illustrate the cases where the direction of the design of the light-emitting pattern is different in each light emitting unit. The present invention is not limited to the above embodiments of the light-emitting pattern of the organic EL element. For example, the light-emitting pattern of the first light emitting unit 6 may be “∘”. The light-emitting pattern of the second light emitting unit 10 may be “X”. In this way, the shape of the design of the light-emitting pattern may be different.

In addition, in each light emitting unit, part of the patterning shape of the light emitting unit may be identical in a stacking direction, but the other part of the patterning shape of the light emitting unit may be different.

Further, in an organic EL element of the present invention, the anode (first electrode) 4 and the supporting substrate 2 as shown in FIG. 1 may be made of materials with low transparency. The cathode (second electrode) 12 may be made of materials with high transparency. In this case, the cathode 12 is the “electrode at the light-emitting surface side” and the light emitting unit 10 is the “first light emitting unit most closely positioned to the electrode at the light-emitting surface side”.

Note that the anode (first electrode) 4 and the supporting substrate 2 as shown in FIG. 1 may be made of materials with high transparency and the cathode (second electrode) 12 may also be made of materials with high transparency. In this case, light can be emitted through both surfaces of the organic EL element. The “electrode at the light-emitting surface side” in this case refers to an electrode at the side where the element can be more appropriately irradiated with light during a light irradiation process. That is, this refers to an electrode at the side with higher transparency.

<<Organic Functional Layer Subjected to Patterning Using Mask During Formation of Organic Functional Layer>>

Among organic functional layers of patterning subject for an organic EL element of the present invention, the following describes an organic functional layer subjected to patterning using a mask during formation of the organic functional layer (hereinafter, appropriately referred to as an “organic functional layer of subject for a film formation mask”).

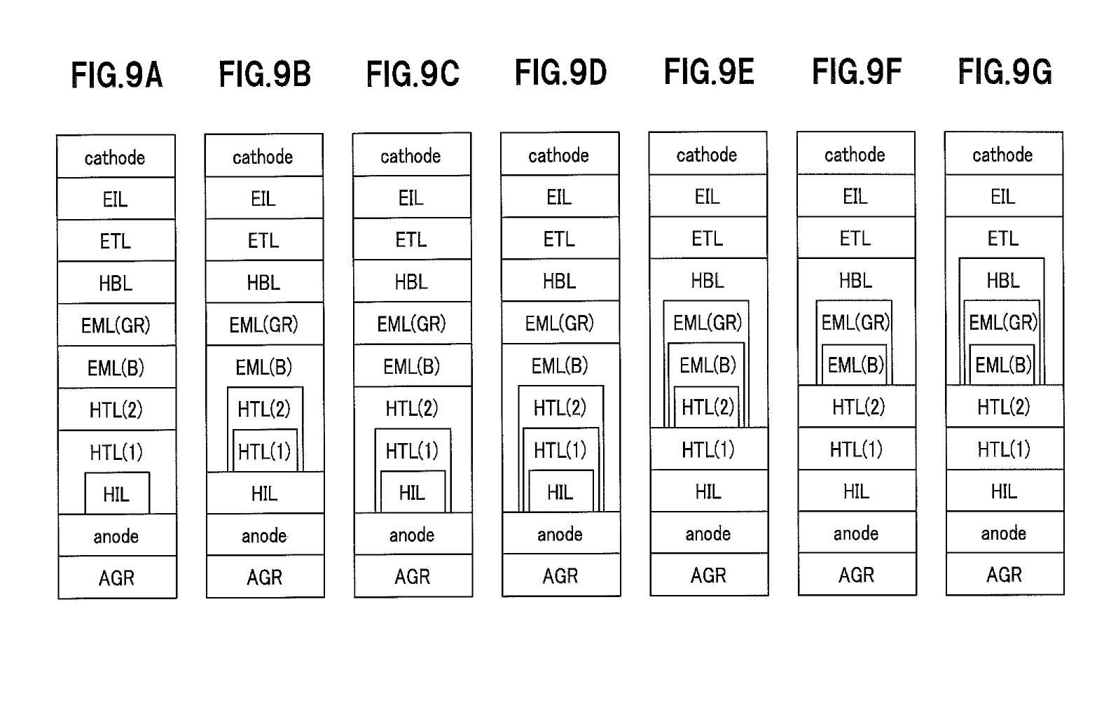

For example, FIG. 9 illustrates that a light emitting unit of an organic EL element of the present invention may include a hole injection layer: HIL/first hole transport layer: HTL (1)/second hole transport layer: HTL (2)/blue light-emitting layer EML (B)/green light-emitting layer: EML (GL)/hole blocking layer: HBL/electron transport layer: ETL/electron injection layer: EIL. In this case, the organic functional layer of subject for a film formation mask may include at least one layer among the above layers. Specifically, a light emitting unit of an organic EL element of the present invention may include any of configurations (a) to (g) in FIG. 9. The organic functional layer of subject for a film formation mask may include only the electron injection layer or the electron transport layer.

In this regard, however, when the materials as described above are used to form each layer, the organic functional layer of subject for a film formation mask preferably includes a hole injection layer (e.g., (a), (c), and (d) of FIG. 9). More preferred is only the hole injection layer (e.g., (a) of FIG. 9). In this way, the organic functional layer of subject for a film formation mask is limited. By doing so, a contrast between a light-emitting portion and a non-light-emitting area is sharp during light emission, and a light-emitting pattern can be thus suitably displayed.

<Thickness of Hole Injection Layer>

The organic functional layer of subject for a film formation mask may be a hole injection layer. In this case, when the hole injection layer has a thickness of less than 2 nm, a light-emitting pattern may become fuzzy during light emission. By contrast, when the hole injection layer has a thickness of more than 50 nm, a leak frequency increases in a step portion between a hole injection layer formation site and a non-formation site. Also, a light-emitting pattern may be visually observed when no light is emitted.

Accordingly, when the organic functional layer of subject for a film formation mask is a hole injection layer, the hole injection layer has a thickness of preferably from 2 to 50 nm and more preferably from 2 to 30 nm.

<Thickness of Hole Transport Layer>

The organic functional layer of subject for a film formation mask may be a hole injection layer. Also, a hole injection layer may be positioned next to a hole transport layer. In this case, when the hole transport layer has a thickness of less than 15 nm, the organic EL element has reduced durability. By contrast, when the hole transport layer has a thickness of more than 200 nm, a color difference during a change in viewing angle becomes larger. At the same time, an amount of absorption of light generated in a light-emitting layer increases, which may result in a fuzzy light-emitting pattern during light emission.

Accordingly, when the organic functional layer of subject for a film formation mask is a hole injection layer and a hole transport layer is positioned next to the hole injection layer, the hole transport layer has a thickness of preferably from 15 to 200 nm and more preferably from 20 to 150 nm.

The following describes a method for producing an organic EL element of the present invention.

<<Method for Producing Organic EL Element>>

A method for producing an organic EL element of the present invention includes a patterning process of subjecting at least one organic functional layer constituting each light emitting unit to patterning. In the patterning process of the method for producing an organic EL element according to the embodiment, patterning for all the light emitting units may be the same or each light emitting unit may have a different patterning.

Note that there are three types of patterning in a patterning process. First, their descriptions are divided into three cases to focus on the patterning.

<Case of Performing Patterning in Laminating Process>

Patterning of an organic functional layer constituting each light emitting unit may be patterning using a mask during formation of an organic functional layer. In this case, in a laminating process (A), a mask is used to stack an organic functional layer subjected to patterning, and the other layers are stacked without using a mask. Then. a sealing process (B) is carried out. Note that in this case, a light irradiation process (C) is unnecessary.

For example, the above method may be used to perform patterning of the first light emitting unit 6 as illustrated in FIG. 2A. In this case, during film deposition of the organic functional layer 6a of the first light emitting unit 6, a metal mask having an opening corresponding to the shape shown in FIG. 2A may be used to perform vapor deposition to form the organic functional layer 6a shown in FIG. 2A.

In addition, the above method may also be used to perform patterning of the second light emitting unit 10 as illustrated in FIG. 2B. In this case, during film deposition of the organic functional layer 10a of the second light emitting unit 10, a metal mask having an opening corresponding to the shape shown in FIG. 2B may be used to likewise perform vapor deposition to form the organic functional layer 10a shown in FIG. 2B.

<Case of Performing Patterning in Light Irradiation Process>

Patterning of an organic functional layer in a patterning process may be patterning using light irradiation after formation of an organic functional layer. In this case, in a laminating process (A), each layer is stacked without using a mask. Next, a sealing process (B) is carried out. Then, a light irradiation process (C) is carried out.

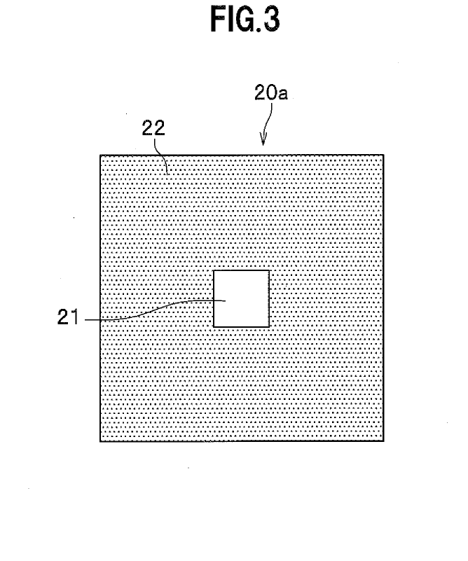

For example, the above method may be used to perform patterning of the first light emitting unit 6 as illustrated in FIG. 2A. In this case, the laminating process (A) and the sealing process (B) are carried out. Then, a mask plate 20a, which has been processed so as not to pass light through a non-irradiated region 21 shown in FIG. 3, is placed on the surface of the supporting substrate 2 (see FIG. 1). Then, the mask plate 20a is irradiated with light having an amount of irradiation sufficient enough to modify the organic functional layer in the first light emitting unit 6, so that emission brightness of a region surrounding the square (i.e., an irradiated region 22) may be modified (decreased).

In addition, the above method may also be used to perform patterning of the second light emitting unit 10 as illustrated in FIG. 2B. In this case, an amount of irradiation of light with which the mask plate 20a is irradiated may be increased to an amount of irradiation sufficient enough to modify the organic functional layers in not only the first light emitting unit 6 but also the second light emitting unit 10 or its irradiation time may be made longer.

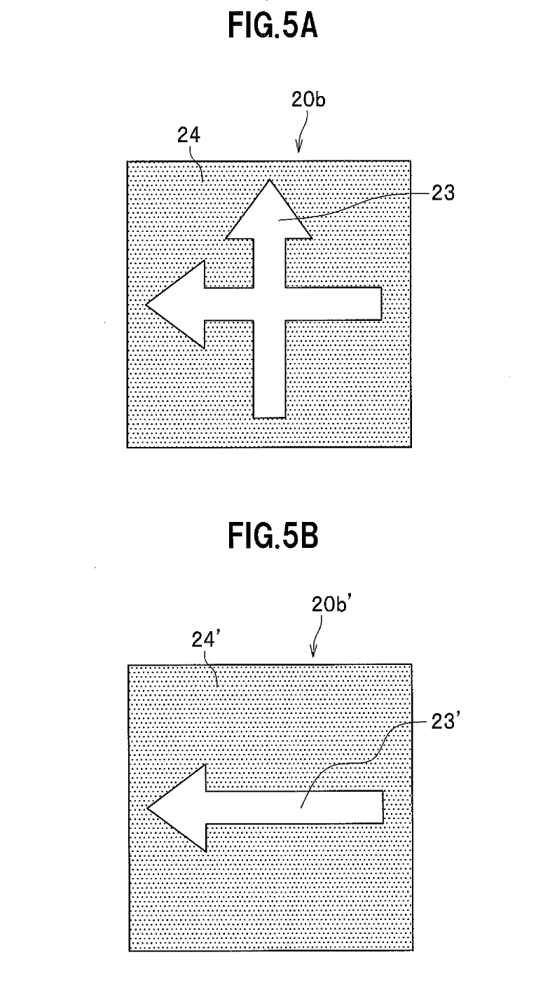

In addition, for example, the above method may be used to perform patterning of the first light emitting unit 6 as illustrated in FIG. 4A. In this case, the laminating process (A) and the sealing process (B) are carried out. Then, a mask plate 20b′, which has been processed so as not to pass light through a non-irradiated region 23′ shown in FIG. 5B, is placed on the surface of the supporting substrate 2 (see FIG. 1). After that, the mask plate 20b′ is irradiated with light having an amount of irradiation sufficient enough to modify the organic functional layer in the first light emitting unit 6, so that emission brightness of a region surrounding the arrow shape (i.e., an irradiated region 24′) may be modified (decreased).

However, with regard to the second light emitting unit 10 as illustrated in FIG. 4B, when the above patterning method is used to perform patterning (i.e., patterning using only light irradiation), part of the luminescent region of the first light emitting unit 6 is also irradiated with light. Thus, this is not preferable.

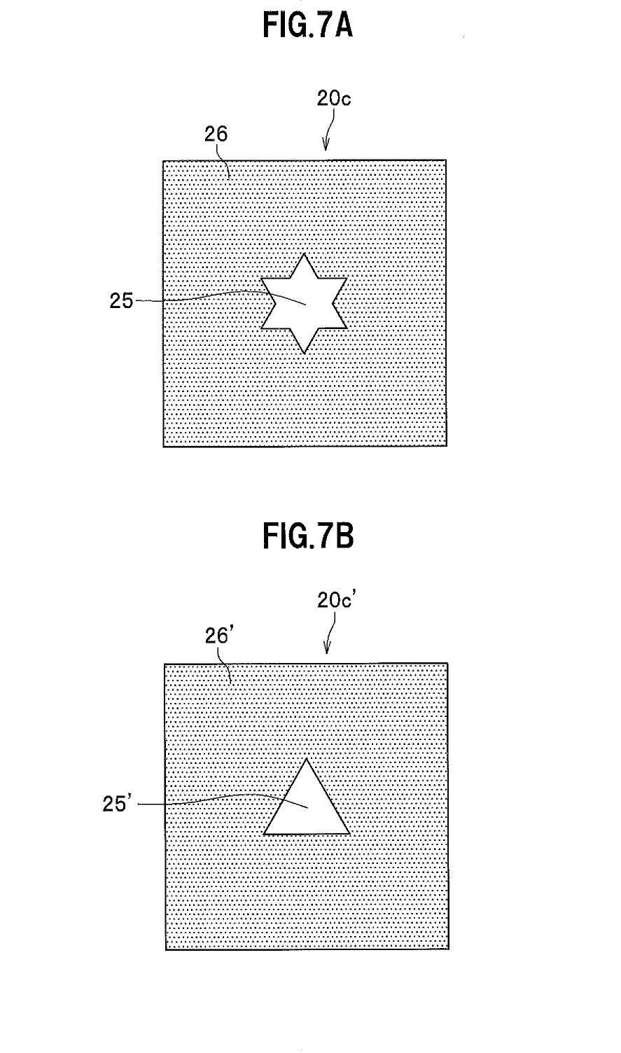

In addition, for example, the above method may be used to perform patterning of the first light emitting unit 6 as illustrated in FIG. 6A. In this case, the laminating process (A) and the sealing process (B) are carried out. Then, a mask plate 20c′, which has been processed so as not to pass light through a non-irradiated region 25′ shown in FIG. 7B, is placed on the surface of the supporting substrate 2 (see FIG. 1). After that, the mask plate 20c′ is irradiated with light having an amount of irradiation sufficient enough to modify the organic functional layer in the first light emitting unit 6, so that emission brightness of a region surrounding the triangle (i.e., an irradiated region 26′) may be modified (decreased).

However, with regard to the second light emitting unit 10 as illustrated in FIG. 6B, when the above patterning method is used to perform patterning (i.e., patterning using only light irradiation), part of the luminescent region of the first light emitting unit 6 is also irradiated with light. Thus, this is not preferable.

<Case of Performing Patterning in Stacking and Light Irradiation Process>

Patterning of an organic functional layer in a patterning process may be patterning using a mask during formation of an organic functional layer and using light irradiation after the formation of the organic functional layer. In this case, in a laminating process (A), a mask is used to stack at least one organic functional layer subjected to patterning, and the other layers are stacked without using a mask. Then, a sealing process (B) is carried out. After that, a light irradiation process (C) is carried out.

For example, the above method may be used to perform patterning of the first light emitting unit 6 and the second light emitting unit 10 as illustrated in FIG. 4. In this case, during film deposition of the organic functional layer 6b of the first light emitting unit 6, a metal mask having an opening corresponding to the shape shown in FIG. 4A is used to perform vapor deposition to form the organic functional layer 6b shown in FIG. 4A. Next, during film deposition of the organic functional layer 10b of the second light emitting unit 10, a metal mask having an opening corresponding to the shape shown in FIG. 4B is used to likewise perform vapor deposition to form the organic functional layer 10b shown in FIG. 4B. Then, the laminating process (A) and the sealing process (B) are carried out. Subsequently, a mask plate 20b, which has been processed so as not to pass light through a non-irradiated region 23 shown in FIG. 5A, is placed on the surface of the supporting substrate 2 (see FIG. 1). After that, the mask plate 20b is irradiated with light having an amount of irradiation sufficient enough to modify the organic functional layers in the first light emitting unit 6 and the second light emitting unit 10, so that emission brightness of a region surrounding the two superimposed arrows (i.e., an irradiated region 24) may be modified (decreased).

In addition, for example, the above method may be used to perform patterning of the first light emitting unit 6 and the second light emitting unit 10 as illustrated in FIG. 6. In this case, during film deposition of the organic functional layer 6c of the first light emitting unit 6, a metal mask having an opening corresponding to the shape shown in FIG. 6A is used to perform vapor deposition to form the organic functional layer 6c shown in FIG. 6A. Next, during film deposition of the organic functional layer 10c of the second light emitting unit 10, a metal mask having an opening corresponding to the shape shown in FIG. 6B is used to likewise perform vapor deposition to form the organic functional layer 10c shown in FIG. 6B. Then, the laminating process (A) and the sealing process (B) are carried out. Subsequently, a mask plate 20c, which has been processed so as not to pass light through a non-irradiated region 25 shown in FIG. 7A, is placed on the surface of the supporting substrate 2 (see FIG. 1). After that, the mask plate 20c is irradiated with light having an amount of irradiation sufficient enough to modify the organic functional layers in the first light emitting unit 6 and the second light emitting unit 10, so that emission brightness of a region surrounding the hexagram shape (i.e., an irradiated region 26) may be modified (decreased).

The following exemplifies the case of performing patterning of two light emitting units during the laminating process and the light irradiation process. FIG. 1 is used to further describe the above-described (A) laminating process, (B) sealing process, and (C) light irradiation process.

(A) Laminating Process

A method for producing an organic EL element 1 of the present invention includes a laminating process of stacking, on a supporting substrate 2, an anode (first electrode) 4, a first light emitting unit 6, an intermediate metal layer 8, a second light emitting unit 10, and a cathode (second electrode) 12.

First, a supporting substrate 2 is prepared. Next, an anode 4 is produced on the supporting substrate 2 so as to form a thin film made of anode material at a film thickness of 1 μm or less and preferably from 10 to 200 nm according to a method such as vapor deposition and/or sputtering. At the same time, an extraction electrode 4a, which is connected to an external power source, is produced at a terminal portion of the anode 4 by using an appropriate method such as vapor deposition.

Then, on the anode are stacked, in sequence, a hole injection layer, a hole transport layer, a light-emitting layer, an electron transport layer, and an electron injection layer constituting the first light emitting unit 6.

Note that when film deposition of the first light emitting unit 6 is carried out, it is possible to select a metal mask for film deposition so as to produce a light-emitting pattern different from that of the second light emitting unit 10. When the first light emitting unit 6 and the second light emitting unit 10 have different emission colors, the identical metal mask may be selected.

With regard to the metal mask, the same metal mask may be used for film deposition of all of the hole injection layer, hole transport layer, light-emitting layer, electron transport layer, and electron injection layer. However, in view of a clear light-emitting pattern and film deposition accuracy, the metal mask is preferably used at the time of film deposition of the hole injection layer and the hole transport layer. The metal mask is more preferably used only at the time of film deposition of the hole injection layer.

Examples of a method for forming each of these layers include spin coating, casting, an ink-jet method, vapor deposition, and printing. From the viewpoints that a uniform layer is easily obtained and a pin hole is hardly generated, however, preferred is a vacuum deposition method or a spin coating method. More preferred is a vacuum deposition method. Further, a different formation method may apply to a different layer.

Vapor deposition may be employed for formation of each of these layers, but its vapor deposition conditions vary depending on the types of compounds used, etc. Generally speaking, the boat heating temperature is from 50 to 450° C.; the degree of vacuum is from 1×10⁻⁶ to 1×10⁻² Pa; the deposition rate is from 0.01 to 50 nm/s; the substrate temperature is from −50 to 300° C.; the thickness is from 0.1 to 5 μm. It is preferable that each condition is suitably selected within the above ranges.

After the formation of these layers, a thin film made of material for an intermediate metal layer is produced using vapor deposition to have a thickness of preferably from 0.6 to 5 nm, more preferably from 0.8 to 3 nm, and still more preferably from 0.8 to 2 nm. By doing so, an intermediate metal layer 8 is disposed.

Next, in substantially the same manner as in the film deposition of the first light emitting unit 6, each layer of the second light emitting unit 10 is produced. At this occasion, as described above, a metal mask used for the film formation may be the same as for the first light emitting unit 6 or may be different.

After the second light emitting unit 10 is formed in the above manner, a cathode 12 is produced thereon by using a formation method such as vapor deposition and/or sputtering. At this time, the cathode 12 remains insulated from the intermediate metal layer 8 and the anode 4 because the first light emitting unit 6 and the second light emitting unit 10 are interposed. While keeping this condition, the cathode 12 is subjected to pattern formation so as to extend its terminal portion from over the second light emitting unit 10 to a periphery of the supporting substrate 2.

(B) Sealing Process

The laminating process is followed by a step of sealing the organic EL element 1 (i.e., a sealing process).

Specifically, while terminal portions of the anode 4 (extraction electrode 4a), the cathode 12, and the intermediate metal layer are kept exposed, over the supporting substrate 2 is disposed a sealing member so as to cover at least the first light emitting unit 6 and the second light emitting unit 10.

(C) Light Irradiation Process

Light irradiation makes it possible to modify an light-emitting function of the first light emitting unit 6 and the second light emitting unit 10 to produce the organic EL element 1 having a specific light-emitting pattern.

As used herein, the modification of a light-emitting function by light irradiation means that changing a function of a hole transport material, etc., constituting a light emitting unit modifies a light-emitting function of the light emitting unit.

Any method can be used as a light irradiation method in the light irradiation process and the method is not limited to a particular method as long as light irradiation at predetermined regions of the first light emitting unit 6 and the second light emitting unit 10 (or only the first light emitting unit 6) enables emission brightness to be modified in the predetermined regions.

Then, irradiation light during the light irradiation process may further include ultraviolet light (UV light), visible light, or infrared light. Including UV light, however, is preferable.

As used herein, the UV light refers to an electromagnetic wave with a wavelength of longer than that of X rays and shorter than the shortest wavelength of visible light. Specifically, the UV light has a wavelength of from 1 to 400 nm.

Means for generating UV light and means for irradiating an object with UV light are not particularly limited as long as UV light is generated and an object is irradiated with UV light by using a conventionally known device, etc. Examples of the specific light source include a high-pressure mercury lamp, a low-pressure mercury lamp, a hydrogen (deuterium) lamp, a rare gas (e.g., xenon, argon, helium, neon) discharge lamp, a nitrogen laser, an excimer laser (e.g., XeCl, XeF, KrF, KrCl), a hydrogen laser, a halogen laser, and a harmonic of various visible (LD)-infrared lasers (e.g., THG (Third Harmonic Generation) light of a YAG laser).

It is preferable to carry out such a light irradiation process after the sealing process.

In addition, during the light irradiation process, a light intensity or an irradiation time, etc., may be adjusted to change an amount of light irradiation. By doing so, depending on the amount of light irradiation, emission brightness of the irradiated portions may be modified. Further, adjusting the amount of light irradiation makes it possible to subject only the first light emitting unit 6 to light irradiation, so that the second light emitting unit 10 is not subjected to patterning using light irradiation.

Note that as the amount of light irradiation increases, emission brightness of the light emitting units 6 and 10 is more attenuated. The less the amount of light irradiation, the less the attenuation rate of the emission brightness. Accordingly, when the amount of light irradiation is 0, that is, when no light irradiation is performed, the light emitting units 6 and 10 have the maximum emission brightness.

The above procedure may be adopted to produce an organic EL element 1 having a desired light-emitting pattern. In the production of such an organic EL element 1, it is preferable that a vacuum is used only once and components from the light emitting unit 6 to the cathode 12 are produced in one continuous operation. However, it may be possible that partway through the operation, the supporting substrate 2 is taken out from a vacuum atmosphere and a different formation method may be conducted. At that occasion, it should be considered to operate the process under a dry inert gas atmosphere.

In addition, a DC voltage may be applied to the organic EL element 1 as so produced. In this case, light emission can be observed when a voltage from about 2 to 40 V is applied to electrodes (e.g., the anode 4 is set to “+” and the intermediate metal layer 8 is set to “−”) positioned at both sides of the light emitting unit 6 or 10 which emits light. Alternatively, an AC voltage may be applied. Any wave shape may be used for the applied AC.

At this time, a current flows only through a light-emitting pattern portion. Accordingly, when this case is compared with a case of using an LED in which light is guided through an unnecessary portion, power consumption can be decreased.

In addition, based on information from a position sensor, for example, a driver IC (Integrated Circuit) may be used to electrically operate the first light emitting unit 6 and the second light emitting unit 10.

<<Applications of Organic EL Element>>

Organic EL elements according to embodiments of the present invention are suitably applicable to various devices.

The following describes an organic electroluminescence module (hereinafter, appropriately referred to as an “organic EL module”) as an example.

<<How to Construct Organic EL Module>>

In an organic EL module of the present invention, a conductive material (member) is connected to an anode and a cathode of at least one organic EL element. Further, the conductive material is connected to a circuit board, etc., to produce a package having an independent function per se.

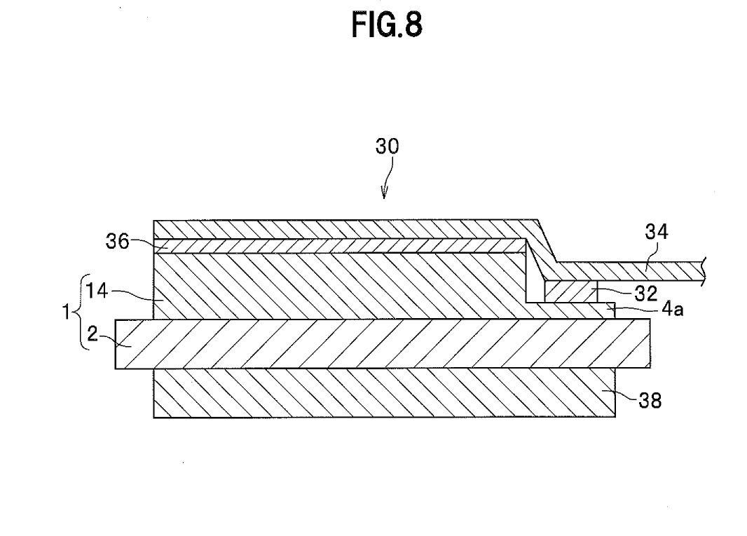

FIG. 8 illustrates an organic EL module of the present invention.

As illustrated in FIG. 8, an organic EL module 30 primarily includes an organic EL element 1, an anisotropic conductive film (ACF) 32, and a flexible printed circuit (FPC) board 34.

The organic EL element 1 has a lamination 14 including a supporting substrate 2, electrodes, and various organic functional layers. An anode 4 (see FIG. 1) extends to a terminal portion of the supporting substrate 2, the portion having thereon no lamination 14. This extraction electrode 4a is electrically connected via the anisotropic conductive film 32 to the FPC board 34.

The FPC board 34 is bonded using an adhesive 36 on the organic EL element 1 (lamination 14). The FPC board 34 is also connected to a driver IC and/or a PC board (not shown).

Although not depicted in FIG. 8, an extraction electrode is formed with respect to the cathode 12 (see FIG. 1). This extraction electrode is electrically connected to the FPC board 34.

In addition, in an embodiment of the present invention, a polarizer 38 may be disposed at the light-emitting surface side of the supporting substrate 2. Instead of the polarizer 38, a half-mirror and/or a black filter may be used. This configuration makes it possible for the organic EL module 30 of the present invention to display a black color which cannot be displayed using light guide dots in an LED.

<Anisotropic Conductive Film (32)>

An anisotropic conductive film of the present invention can be produced by dispersing into a binder conductive particles including, for example, a metal core such as gold, nickel, and silver or a resin core plated with gold.

Examples of the binder used include a thermoplastic resin and a thermal curing resin. Among them, preferred is a thermal curing resin. More preferred is a resin using an epoxy resin.

Examples of a filler that can be suitably used include an anisotropic conductive film in which nickel fibers (fibrous materials) are oriented.

Also, in an embodiment of the present invention, a conductive paste-like fluid material such as a silver paste may be used as an alternative for the anisotropic conductive film.

<Polarizer (38)>

Examples of a polarizer of the present invention include a commercially available polarizing plate or a circularly polarizing plate.

A polarizing film, which is a major component of the polarizing plate, refers to a device in which only light with a predetermined orientation angle can pass through a polarization plane. Representative examples of the polarizing film include a polyvinyl alcohol-based polarizing film. This film can be produced by dyeing a polyvinyl alcohol-based film with either iodine or dichroic dye. The polarizing film may be produced by forming a film using a polyvinyl alcohol aqueous solution and by subjecting the film to uniaxial drawing, followed by dyeing. Alternatively, the film is first dyed, and then subjected to uniaxial drawing and preferably durability treatment using a boron compound. The polarizing film that can be preferably used has a film thickness of from 5 to 30 μm and preferably from 8 to 15 μm. In an embodiment of the present invention, such a polarizing film can be suitably used.

In addition, a commercially available polarizing plate protection film is preferably used. Specific examples include KC8UX2MW, KC4UX, KC5UX, KC4UY, KC8UY, KC12UR, KC4UEW, KC8UCR-3, KC8UCR-4, KC8UCR-5, KC4FR-1, KC4FR-2, KC8UE, and KC4UE (produced by Konica Minolta, Inc.)

An adhesive used to bond the polarizer and the supporting substrate is preferably an optically transparent adhesive with suitable viscoelasticity and adhesive properties.

Specific examples include an acrylic copolymer, an epoxy-based resin, polyurethane, a silicone-based polymer, polyether, a butyral-based resin, a polyamide-based resin, a polyvinyl alcohol-based resin, and synthetic rubber. Among them, an acrylic copolymer can be preferably used because of most easily controlled viscosity properties and excellent transparency, weather resistance, and durability, etc.

The adhesive is coated on the board. Then, a film may be formed and cured using, for example, drying, chemical curing, thermal curing, hot melting, and/or photocuring.

<<Method for Producing Organic EL Module>>

An organic EL module can be produced by using a predetermined procedure to connect an extraction electrode of an anode, which supplies a current, and an extraction electrode (not shown) of a cathode, which receives the current.

When the connection procedure uses an anisotropic conductive film, in particular, the procedure includes: a step of temporarily bonding the anisotropic conductive film at a temporary bonding temperature; and a step of pressing conductive particles, which play an actual role in achieving an electrical connection in the anisotropic conductive film. By doing so, the anisotropic conductive film is electrically connected to the extraction electrodes.

When the supporting substrate is made of a film substrate, an anisotropic conductive film (e.g., an MF series film produced by Hitachi Chemical Company, Ltd.) having a pressing temperature of 100 to 150° C. may be selected so as to reduce heat damage to the film substrate.

More specifically, as the first step, a step of temporarily bonding an anisotropic conductive film is carried out. In this step, an ACF-bonding device (LD-03 produced by OHASHI ENGINEERING), for example, may be used. The temperature of a heat tool for temporary bonding may be set to about 80° C. After the organic EL element and the anisotropic conductive film are positioned, bonding may be conducted at a predetermined pressure (from 0.1 to 0.3 MPa) while pressing for about 5 sec.

Subsequently, a bonding step (crimping process) may be carried out. In this step, a main pressing device (BD-02 produced by OHASHI ENGINEERING CO., LTD.), for example, may be used. First, the temperature of a heat tool for bonding may be set to from about 130 to 150° C. Next, a contact pad of the FPC board connected to the organic EL element may be positioned at an extraction electrode portion of the organic EL element. After completion of the positioning, the heat tool may be pressed for about 10 sec from the FPC board side at a predetermined pressure (from 1 to 3 MPa) to complete the bonding step. After the bonding, a silicone resin, for example, may be used for potting from the bonding portion side so as to reinforce the attachment of the anisotropic conductive film.

In addition, depending on applications, an adhesive may be used to provide the light-emitting surface side of the supporting substrate with a polarizer, a half-mirror, or a black filter.

### EXAMPLES

The following specifically describes the present invention by referring to Examples. The present invention, however, is not limited to them. Note that the term “%” is used in Examples. Unless otherwise indicated, the term means “% by mass”.

### Example 1

### Production of Organic EL Element

According to the following procedure, an organic EL element 1 including components shown in FIGS. 1 and 4 was produced.

<Preparation of Transparent Substrate>

A polyethylene terephthalate film (ultra-transparent PET Type K; produced by Teijin DuPont Films Japan Limited) at a thickness of 125 μm was used as a transparent substrate.

The film was coated with the following polysilazane-containing solution by using a wireless bar to have an average film thickness of 300 nm after drying. The coated film was heated and dried for 1 min under an atmosphere at a temperature of 85° C. and a humidity of 55% RH. Next, the resulting film was subjected to dehumidification processing while kept for 10 min under an atmosphere at a temperature of 25° C. and a humidity of 10% RH (dew point temperature: −8° C.) to form a polysilazane-containing layer on the transparent substrate.

Then, the transparent substrate having thereon the polysilazane-containing layer was mounted on a production stage of an excimer irradiation apparatus MECL-M-1-200 (produced by M.D.COM, Inc.). After that, the following reforming process conditions 1 were used to perform the reforming process. Finally, the transparent substrate 2 having thereon a polysilazane-modified layer (not shown) at a thickness of 300 nm was produced.

<Polysilazane-Containing Solution>

A dibutyl ether solution containing 10% by mass of perhydropolysilazane (AQUAMICA NN120-10; a non-catalyst type; produced by AZ Electronic Materials, Ltd.) was prepared as a polysilazane-containing solution.

<Reforming Process Conditions 1>

Irradiation wavelength: 172 nm

Lamp gas: Xe

Light intensity of an excimer lamp: 130 mW/cm² (172 nm)

Distance between a sample and a light source: 1 mm

Stage heating temperature: 70° C.

Oxygen level in an irradiation device: 0.5%

Excimer lamp irradiation time: 5 sec

<Formation of Foundation Layer>

The following compound R-1 was deposited at a thickness of 25 nm on the transparent substrate 2 by using a known vapor deposition method to form a foundation layer (not shown).

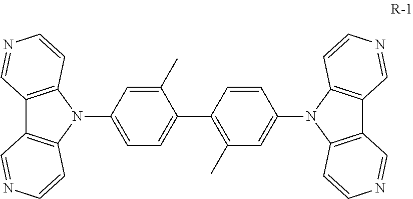 [SMILES: Cc1cc(-n2c3ccncc3c3cnccc32)ccc1-c1ccc(-n2c3ccncc3c3cnccc32)cc1C]

<Formation of First Electrode>

Next, silver was deposited at a thickness of 10 nm on the foundation layer by vapor deposition to prepare a first transparent electrode 4 (i.e., an anode).

<Formation of First Light Emitting Unit>

The transparent substrate 2 having thereon the first transparent electrode 4 was subjected to ultrasonic cleaning using isopropyl alcohol, drying using a dried nitrogen gas, and UV ozone cleaning for 5 min. Next, this transparent substrate 2 was mounted on a substrate holder of a commercially available vacuum evaporator.

Then, a component material for each layer was placed in each of evaporation crucibles in the vacuum evaporator and each crucible was filled with an optimal amount of the material to produce each element. The evaporation crucibles were made of molybdenum or tungsten resistance heating materials.

(Formation of Hole Injection Layer)

After the pressure was reduced to a degree of vacuum of 1×10⁻⁴ Pa, an evaporation crucible containing a compound M-4 was heated by turning on electricity. Then, the compound was deposited at a deposition rate of 0.1 nm/sec on the transparent supporting substrate to form a hole injection layer at a film thickness of 15 nm.

(Formation of Hole Transport Layer)

Next, a compound M-2 was deposited thereon at a deposition rate of 0.1 nm/sec to form a hole transport layer at a film thickness of 40 nm (Formation of Fluorescent Layer)

Next, a compound BD-1 and a compound H-1 were used for co-vapor deposition at a deposition rate of 0.1 nm/sec to have a concentration of the compound BD-1 of 5% and a concentration of the compound H-1 of 95%. Then, a fluorescent layer (light-emitting layer) that was able to emit blue light was formed at a film thickness of 15 nm.

(Formation of Phosphorescent Layer)

Next, a compound GD-1, a compound RD-1, and a compound H-2 were used for co-vapor deposition at a deposition rate of 0.1 nm/sec to have a concentration of the compound GD-1 of 17%, a concentration of the compound RD-1 of 0.8%, and a concentration of the compound H-2 of 82.2%. Then, a phosphorescent layer (light-emitting layer) that was able to emit yellow light was formed at a film thickness of 15 nm.

(Formation of Electron Transport Layer)

Next, a compound E-1 was deposited thereon at a deposition rate of 0.1 nm/sec to form an electron transport layer at a film thickness of 30 nm.

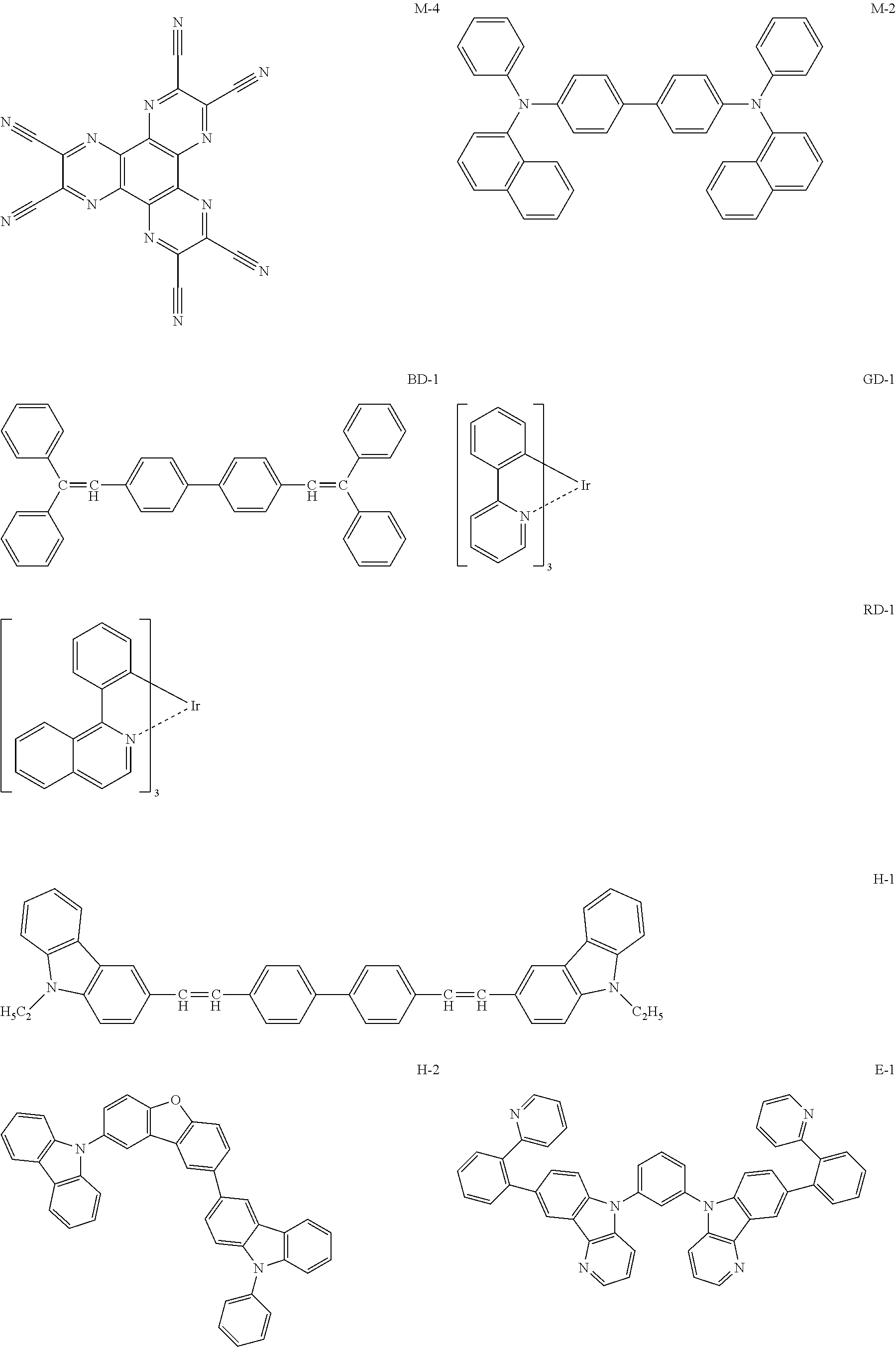

(Formation of Electron Injection Layer)

Next, LiF was deposited at a film thickness of 1.5 nm to form a LiF layer that was an electron injection layer.

Note that the above vapor deposition was carried out, provided that when a layer as a lamination-1 patterning layer designated in Table 1 was formed, vapor deposition was conducted using a metal mask that was able to create patterning of the design shown in FIG. 4A. In addition, when the thickness of the patterning layer is designated in Table 1, the thickness designated in the table was used instead of the above-described thickness.

(Formation of Intermediate Metal Layer)

Next, an aluminum film was deposited at a thickness of 10 nm by vapor deposition to form an Al layer that was an intermediate metal layer.

<Formation of Second Light Emitting Unit>

(Formation of Hole Injection Layer)

Next, a compound M-4 was deposited thereon at a deposition rate of 0.1 nm/sec to form a hole injection layer at a film thickness of 15 nm.

(Formation of Hole Transport Layer)

Next, a compound M-2 was deposited thereon at a deposition rate of 0.1 nm/sec to form a hole transport layer at a film thickness of 50 nm.

(Formation of Fluorescent Layer)

Next, a compound BD-1 and a compound H-1 were used for co-vapor deposition at a deposition rate of 0.1 nm/sec to have a concentration of the compound BD-1 of 5% and a concentration of the compound H-1 of 95%. Then, a fluorescent layer (light-emitting layer) that was able to emit blue light was formed at a film thickness of 15 nm.

(Formation of Phosphorescent Layer)

Next, a compound GD-1, a compound RD-1, and a compound H-2 were used for co-vapor deposition at a deposition rate of 0.1 nm/sec to have a concentration of the compound GD-1 of 17%, a concentration of the compound RD-1 of 0.8%, and a concentration of the compound H-2 of 82.2%. Then, a phosphorescent layer (light-emitting layer) that was able to emit yellow light was formed at a film thickness of 15 nm.

(Formation of Electron Transport Layer)

Next, a compound E-1 was deposited thereon at a deposition rate of 0.1 nm/sec to form an electron transport layer at a film thickness of 30 nm.

(Formation of Electron Injection Layer)

Next, LiF was deposited at a thickness of 1.5 nm to form an electron injection layer.

<Formation of Second Electrode>

Next, aluminum was deposited at a thickness of 110 nm to form a second electrode (cathode).

Note that the above vapor deposition was carried out, provided that when a layer as a lamination-2 patterning layer designated in Table 1 was formed, vapor deposition was conducted using a metal mask that was able to create patterning of the design shown in FIG. 4B. In addition, when the thickness of the patterning layer is designated in Table 1, the thickness designated in the table was used instead of the above-described thickness.

<Production of Transparent Sealing Substrate>

In substantially the same manner as in the above transparent substrate 2, a polyethylene terephthalate film (ultra-transparent PET Type K; produced by Teijin DuPont Films Japan Limited) at a thickness of 125 μm was coated with the same polysilazane-containing solution. Then, the resulting film was treated using an excimer lamp to form a gas barrier layer. Subsequently, a transparent sealing substrate with a gas barrier layer was obtained.

<Sealing of Organic EL Element>

An epoxy-based thermal curing adhesive (ELEPHANE® CS, produced by TOMOEGAWA Co., Ltd.) was used as an adhesive to bond the transparent sealing substrate. A vacuum press so as to press the gas barrier layer of the transparent sealing member onto the organic EL element 1 was carried out under conditions at a temperature of 80° C. under a load of 0.04 MPa for 20 sec of vacuum suction (1×10⁻³ MPa or less) and 20 sec of pressing in a glove box at an oxygen level of 10 ppm or less and a moisture concentration of 10 ppm or less.

Then, the resulting transparent sealing member was heated for 30 min on a hot plate at 110° C. in the glove box to subject the bonded layer to thermal curing. Finally, the organic EL element 1 was completed.

Note that a UV absorbing filter (produced by ISUZU GLASS CO., LTD.) and the mask plate illustrated in FIG. 5B were attached under a reduced pressure to Sample 101 or 108 while the plate and filter was placed on the supporting substrate surface opposite to the surface having thereon the above respective layers. Then, a UV tester (SUV-W151, produced by IWASAKI ELECTRIC CO., LTD.) was used to irradiate the samples with UV light (an irradiation output; 100 mW/cm²) for patterning. With regard to Sample 101, when the lamination-2 patterning was formed, the mask plate shown in FIG. 5B was rotated 90 degrees and used for the irradiation. In addition, when the lamination-2 patterning of Sample 101 was formed, a light irradiation time was 3 hours. When the lamination-1 patterning of Sample 101 or 108 was formed, a light irradiation time was 1 hour and a half that was half of the above light irradiation time.

Also, in the UV absorbing filter used, a light component with a wavelength of 320 nm or less had a light transmittance of 50% or less (i.e., a cutoff wavelength: 320 nm).

The above procedure was used to produce Samples 101 to 108.

<<Evaluation of Samples>>

Samples 101 to 108 as so produced were used to evaluate power consumption and patterning characteristics as follows.

<Power Consumption>

Power consumption was calculated for each lamination when the light-emitting portion (i.e., the arrow portion (a luminescent area of 9 mm²) positioned in a total area (9 mm×9 mm □) of the organic functional layer as illustrated in FIG. 4) of the samples prepared had a front luminance of 1000 cd/m². Finally, the power consumptions of two laminations were averaged. With regard to the power consumption, a relative value was determined when an average of the power consumptions of two laminations in Sample 101 was set to 100. Note that a spectroradiometer CS-2000 (produced by Konica Minolta Sensing, Inc.) was used for emission brightness measurements.

Then, the relative value of the power consumption was evaluated as follows:

A (Excellent): 90 or less;

B (Good): more than 90 and less than 100;

C (Acceptable): from 100 to 105; and

D (Poor): more than 105.

<Patterning Characteristics>

The electricity for each lamination was turned on separately so as to allow the light-emitting portion (i.e., the arrow portion (a luminescent area of 9 mm²) positioned in a total area (9 mm×9 mm □) of the organic functional layer as illustrated in FIG. 4) of the samples prepared to have a front luminance of 1000 cd/m². Then, a front luminance of the light-emitting portion or non-light-emitting area (i.e., the portion other than the arrow portion illustrated in FIG. 4) was measured. After that, a ratio (contrast ratio) of a luminance of the light-emitting portion to a luminance of the non-light-emitting area was calculated for each lamination. Finally, the ratios of two laminations were averaged. Note that a spectroradiometer CS-2000 (produced by Konica Minolta Sensing, Inc.) was used for emission brightness measurements.

Here, the ratio of “a luminance of the light-emitting portion/a luminance of the non-light-emitting area” was evaluated as follows:

A (Excellent): 1000 or more;

B (Good): less than 1000 and 200 or more;

C (Acceptable): less than 200 and 100 or more; and

D (Poor): less than 100.

TABLE 1

| Sam- | Lamination-1 (First Light emitting unit) | | | Lamination-2 (Second Light emitting unit) | | | Evaluations | |
|---|---|---|---|---|---|---|---|---|
| ple | Patterning | Patterning Layer | | Patterning | Patterning Layer | | Power | Patterning |
| No. | Method | Type | Thickness (nm) | Method | Type | Thickness (nm) | Consumption | Characteristics |
| 101 | UV Irradiation | — | — | UV Irradiation | — | — | C | D |
| 102 | Deposition | Electron | 25 | Deposition | Electron | 25 | B | B |
| | Mask | Injection Layer | | Mask | Injection Layer | | | |
| 103 | Deposition | Electron | 25 | Deposition | Electron | 25 | B | B |
| | Mask | Transport | | Mask | Transport | | | |
| | | Layer | | | Layer | | | |
| 104 | Deposition | Light Emitting | 25 | Deposition | Light | 25 | B | B |
| | Mask | Layer | | Mask | Emitting Layer | | | |
| 105 | Deposition | Hole Transport | 25 | Deposition | Hole | 25 | B | B |
| | Mask | Layer | | Mask | Transport | | | |
| 106 | Deposition | Hole Injection | 12.5 + 12.5 | Deposition | Hole Injection | 12.5 + 12.5 | B | B |
| | Mask | Layer + Hole | | Mask | Layer + Hole | | | |
| | | Transport | | | Transport | | | |
| | | Layer | | | Layer | | | |
| 107 | Deposition | Hole Injection | 25 | Deposition | Hole Injection | 25 | A | A |
| | Mask | Layer | | Mask | Layer | | | |
| 108 | UV Irradiation | — | — | Deposition | Hole Injection | 25 | B | B |
| | | | | Mask | Layer | | | |

### Analysis of Results

### Example 1

The results of Table 1 have clearly demonstrated better power consumption and patterning characteristics in Samples 102 to 107, which had been patterned using a vapor deposition mask, than in Sample 101, which had been patterned using UV light irradiation. Sample 107, in which only the hole injection layer was subjected to patterning using a vapor deposition mask, has particularly produced remarkable results with respect to its power consumption.

In addition, Sample 108 has produced reasonable results with respect to its power consumption and patterning characteristics. Thus, it has been found that even if a procedure includes subjecting the lamination-1 to patterning using UV light and subjecting the lamination-2 to patterning using a vapor deposition mask, a better organic EL element can be produced.

Note that any of the samples has produced a uniform light-emitting pattern without uneven light emission and their light-emitting patterns were switchable (lamination-1<=>lamination-2).

### Example 2

### Production of Samples

Samples 201 to 210 were produced in substantially the same manner as in the samples of Example 1.

Note that in Example 2, the vapor deposition mask was used for a patterning procedure and the patterning layer was the hole injection layer in all the samples. However, the thicknesses of the hole injection layer and the hole transport layer were modified.

<<Evaluation of Samples>>

Samples 201 to 210 as so produced were used to evaluate durability, visibility at the time of no light emission, and a viewing angle as follows.

<Durability>

With regard to the samples produced (the number of times for evaluation: N=50), a voltage of 5 V was applied between the anode and the intermediate metal layer and between the intermediate metal layer and the cathode for 1000 hours continuously. After the voltage application, a light-emitting status was examined and a yield ((the number of test pieces without leakage/the number of times for evaluation)×100) was calculated.

Then, the yield was evaluated as follows:

A (Excellent): 100%;

B (Good): 95% or more and less than 100%;

C (Acceptable): 85% or more and less than 95%;

D (Poor): 70% or more and less than 85%; and

E (Bad): less than 70%.

<Visibility at the Time of No Light Emission>

With regard to the samples produced, both the light-emitting portion (i.e., the arrow portion (a luminescent area of 9 mm²) positioned in a total area (9 mm×9 mm □) of the organic functional layer as illustrated in FIG. 4) and the non-light-emitting area (the portion other than the arrow portion illustrated in FIG. 4) were visually inspected at the time of no light emission. Next, whether or not the pattern was recognizable was examined.

Then, the results were evaluated as follows:

A (Excellent): No pattern was recognizable;

B (Good): The pattern was slightly recognizable;

C (Acceptable): The pattern was recognizable; and

D (Poor): The pattern was clearly recognizable and was distinct.

<Viewing Angle>

With regard to the samples produced, a scattering film (a light diffusion film (MTN-W1); produced by KIMOTO CO., LTD.) was attached on the surface of the supporting substrate. Next, the electricity for each lamination was turned on separately so as to allow the light-emitting portion (i.e., the arrow portion (a luminescent area of 9 mm²) positioned in a total area (9 mm×9 mm □) of the organic functional layer as illustrated in FIG. 4) to have a front luminance of 1000 cd/m². Then, a color luminance meter (CS-100: Konica Minolta, Inc.) was used to determine a chromaticity (CIE color system (1931)) when the viewing angle was changed from −85 degrees to +85 degrees while the front direction was set to 0 degrees. With regard to chromaticities x and y, Δx and Δy, which represent a difference between the maximum value (max) and the minimum value (min), were calculated using equations (1) and (2). Further, equation (3) was used to calculate a color difference ΔE with respect to each lamination. Finally, the color differences ΔE of two laminations were averaged. Meanwhile, this color difference ΔE was used as an evaluation index for viewing angle dependency.

Then, the color difference ΔE of each sample having thereon the scattering film was evaluated as follows:

A (Excellent): ΔE<0.05;

B (Good): 0.05≦ΔE<0.1;

C (Acceptable): 0.1≦ΔE<0.3; and

D (Poor): 0.3≦ΔE.

Δx′xₘₐₓ−xₘᵢₙ Equation (1)

Δy=yₘₐₓ−yₘᵢₙ Equation (2)

ΔE=\sqrt{Δx²Δy²} Equation (3)

TABLE 2

| | Lamination-1 (First Light emitting unit) | | | | Lamination-2 (Second Light emitting unit) | | | | Evaluations | | |
|---|---|---|---|---|---|---|---|---|---|---|---|
| | | | | Hole | | | | Hole | | Visibility | |
| | | Patterning Layer | | Transport | | Patterning Layer | | Transport | | during | |
| Sample | Patterning | | Thickness | Thickness | Patterning | | Thickness | Thickness | | No Light | Viewing |
| No. | Method | Type | (nm) | (nm) | Method | Type | (nm) | (nm) | Durability | Emission | Angle |
| 201 | Deposition | Hole Injection | 25 | 20 | Deposition | Hole Injection | 25 | 20 | A | A | A |
| | Mask | Layer | | | Mask | Layer | | | | | |
| 202 | Deposition | Hole Injection | 1 | 20 | Deposition | Hole Injection | 1 | 20 | B | A | A |
| | Mask | Layer | | | Mask | Layer | | | | | |
| 203 | Deposition | Hole Injection | 2 | 20 | Deposition | Hole Injection | 2 | 20 | A | A | A |
| | Mask | Layer | | | Mask | Layer | | | | | |
| 204 | Deposition | Hole Injection | 50 | 20 | Deposition | Hole Injection | 50 | 20 | A | A | A |
| | Mask | Layer | | | Mask | Layer | | | | | |
| 205 | Deposition | Hole Injection | 55 | 20 | Deposition | Hole Injection | 55 | 20 | A | B | A |
| | Mask | Layer | | | Mask | Layer | | | | | |
| 206 | Deposition | Hole Injection | 25 | 10 | Deposition | Hole Injection | 25 | 10 | B | A | A |
| | Mask | Layer | | | Mask | Layer | | | | | |
| 207 | Deposition | Hole Injection | 25 | 50 | Deposition | Hole Injection | 25 | 50 | A | A | A |
| | Mask | Layer | | | Mask | Layer | | | | | |
| 208 | Deposition | Hole Injection | 25 | 100 | Deposition | Hole Injection | 25 | 100 | A | A | A |
| | Mask | Layer | | | Mask | Layer | | | | | |
| 209 | Deposition | Hole Injection | 25 | 200 | Deposition | Hole Injection | 25 | 200 | A | A | A |
| | Mask | Layer | | | Mask | Layer | | | | | |
| 210 | Deposition | Hole Injection | 25 | 210 | Deposition | Hole Injection | 25 | 210 | A | B | B |
| | Mask | Layer | | | Mask | Layer | | | | | |

### Analysis of Results

### Example 2

The results of Table 2 have clearly demonstrated that Samples 201, 203 to 205, and 207 to 210, in which the hole injection layer that was a patterning layer had a thickness of 2 nm or more and the hole transport layer had a thickness of 15 nm or more, have exhibited excellent durability results.

In addition, Samples 201 to 204 and 206 to 209, in which the hole injection layer that was a patterning layer had a thickness of 50 nm or less, have exhibited excellent visibility results at the time of no light emission.

Further, Samples 201 to 209, in which the hole transport layer had a thickness of 200 nm or less, have exhibited excellent viewing angle results.

Note that any of the samples produced a uniform light emitting pattern having no uneven light emission, and were capable of changing the light emitting pattern (i.e., lamination-1<=>lamination-2).

1. An organic electroluminescence element comprising:
a supporting substrate;
a first electrode disposed on the supporting substrate;
N sets of light emitting units each including one or more organic functional layers, where N represents an integer of 2 or more;
(N−1) sets of intermediate metal layers with optical transparency and each disposed between the adjacent light emitting units; and
a second electrode, as being stacked to form the organic electroluminescence element, wherein
at least one organic functional layer of the light emitting unit is a layer subjected to patterning using a mask during formation of the organic functional layer, a layer subjected to patterning via light irradiation after formation of the organic functional layer, or a layer subjected to patterning using a mask during formation of the organic functional layer and further subjected to patterning via light irradiation after the formation of the organic functional layer, with respect to the N sets of light emitting unit, and
the N sets of light emitting units are electrically operable individually or simultaneously.

2. The organic electroluminescence element according to claim 1, wherein
shapes of the patterning in a stacking direction are not the same among the light emitting units; and
in a second to Nth light emitting units excluding a first light emitting unit placed closest to an electrode at a light emitting surface side among the N sets of light emitting units, at least one organic functional layer of each light emitting unit is a layer subjected to patterning using a mask during formation of the organic functional layer, or a layer subjected to patterning using a mask during formation of the organic functional layer and further subjected to patterning via light irradiation after the formation of the organic functional layer.

3. The organic electroluminescence element according to claim 1, wherein the organic functional layer subjected to patterning using a mask during formation of the organic functional layer includes a hole injection layer.

4. The organic electroluminescence element according to claim 3, wherein the organic functional layer subjected to patterning using a mask during formation of the organic functional layer is the hole injection layer.

5. The organic electroluminescence element according to claim 4, wherein the hole injection layer has a thickness of from 2 to 50 nm.

6. The organic electroluminescence element according to claim 4, wherein each of the N sets of light emitting units includes a hole transport layer adjacent to the hole injection layer; and the hole transport layer has a thickness of from 15 to 200 nm.

7. A method for producing an organic electroluminescence element which comprises a supporting substrate; a first electrode disposed on the supporting substrate; N sets of light emitting units including one or more organic functional layers, where N represents an integer of 2 or more; (N−1) sets of intermediate metal layers with optical transparency and each disposed between the adjacent light emitting units; and a second electrode, as being stacked to form the organic electroluminescence element,
the method comprising patterning process of subjecting at least one organic functional layer of each light emitting unit to patterning, wherein
the patterning of the organic functional layer in the patterning process is patterning using a mask during formation of the organic functional layer, patterning using light irradiation after formation of the organic functional layer, or patterning using a mask during formation of the organic functional layer and further via light irradiation after the formation of the organic functional layer.

8. The method for producing an organic electroluminescence element according to claim 7, wherein
shapes of the patterning in a stacking direction are not the same among the light emitting units; and
in a second to Nth light emitting units excluding a first light emitting unit placed closest to an electrode at a light emitting surface side among the N light emitting units, the patterning of the organic functional layer during the patterning process is patterning using a mask during formation of the organic functional layer, or patterning using a mask during formation of the organic functional layer and further via light irradiation after the formation of the organic functional layer.

9. The method for producing an organic electroluminescence element according to claim 7, wherein the organic functional layer subjected to patterning using a mask during formation of the organic functional layer includes a hole injection layer.

10. The method for producing an organic electroluminescence element according to claim 9, wherein the organic functional layer subjected to patterning using a mask during formation of the organic functional layer is the hole injection layer.

11. The method for producing an organic electroluminescence element according to claim 10, wherein the hole injection layer has a thickness of from 2 to 50 nm.

12. The method for producing an organic electroluminescence element according to claim 10, wherein
each of the N light emitting units includes a hole transport layer next to the hole injection layer; and
the hole transport layer has a thickness of from 15 to 200 nm.

13. An organic electroluminescence module comprising the organic electroluminescence element comprising:
a supporting substrate;
a first electrode disposed on the supporting substrate;
N sets of light emitting units each including one or more organic functional layers, where N represents an integer of 2 or more;
(N−1) sets of intermediate metal layers with optical transparency and each disposed between the adjacent light emitting units; and
a second electrode, as being stacked to form the organic electroluminescence element, wherein
at least one organic functional layer of the light emitting unit is a layer subjected to patterning using a mask during formation of the organic functional layer, a layer subjected to patterning via light irradiation after formation of the organic functional layer, or a layer subjected to patterning using a mask during formation of the organic functional layer and further subjected to patterning via light irradiation after the formation of the organic functional layer, with respect to the N sets of light emitting unit, and
the N sets of light emitting units are electrically operable individually or simultaneously.

14. The organic electroluminescence module according to claim 13, further comprising a polarizer, a half-mirror, or a black filter on a surface of the supporting substrate of the organic electroluminescence element.
